(19) United States
(12) Patent Application Publication
(10) Pub. No.: US 2022/0352261 A1
(43) Pub. Date: Nov. 3, 2022

(54) ELECTRO-OPTICAL DEVICE AND ELECTRONIC APPARATUS

(71) Applicant: SEIKO EPSON CORPORATION, Tokyo (JP)

(72) Inventors: Jun IROBE, Chino-Shi (JP); Yuiga HAMADE, Matsumoto-Shi (JP)

(73) Assignee: SEIKO EPSON CORPORATION, Tokyo (JP)

(21) Appl. No.: 17/732,484

(22) Filed: Apr. 28, 2022

(30) Foreign Application Priority Data
Apr. 30, 2021 (JP) 2021-077352

(51) Int. Cl. H01L 27/32; H01L 51/52

(52) U.S. Cl. CPC H01L 27/3216; H01L 51/5281; H01L 27/322

(57) ABSTRACT

An electro-optical device includes: a first light-emitting region that emits light in a first wavelength range; a second light-emitting region disposed at a position adjacent to the first light-emitting region in a first direction and that emits light in a second wavelength range; a third light-emitting region disposed at a position adjacent to the first light-emitting region in a second direction and that emits light in a third wavelength range; a fourth light-emitting region disposed at a position adjacent to the second light-emitting region in the second direction and that emits light in a third wavelength range; a first coloring layer provided overlapping the first light-emitting region; a second coloring layer provided overlapping the second light-emitting region; a third coloring layer provided overlapping the third and fourth light-emitting regions; and a light-shielding portion including a first light-shielding portion provided in an island shape to overlap a region between the third and fourth light-emitting regions and that blocks at least the light in the third wavelength range.

The present application is based on, and claims priority from JP Application Serial Number 2021-077352, filed Apr. 30, 2021, the disclosure of which is hereby incorporated by reference herein in its entirety.

### BACKGROUND

### 1. Technical Field

The present disclosure relates to an electro-optical device and an electronic apparatus.

### 2. Related Art

Electro-optical devices including light-emitting elements such as organic electroluminescence (EL) elements are known. In this type of devices, for example, as disclosed in JP-A-2019-117941, there is generally provided a color filter that transmits, of the light from the light-emitting element, light in a predetermined wavelength range.

The electro-optical device described in JP-A-2019-117941 includes four sub-pixels for each of a plurality of pixels disposed in a matrix in an X direction and a Y direction orthogonal to the X direction. The four sub-pixels are composed of an R pixel and a G pixel that are adjacent to each other in the X direction, and two B pixels that are adjacent to the R pixel and the G pixel in the Y direction and that are adjacent to each other in the X direction. A color filter of the corresponding color is disposed on each of these sub-pixels.

In the electro-optical device described in JP-A-2019-117941, a plurality of rows in which color filters corresponding to R pixels and G pixels are alternately and repeatedly arranged in the X direction, and a plurality of rows in which only color filters corresponding to B pixels are arranged in the X direction are alternately disposed in the Y direction.

Here, in the rows of the color filters corresponding to the R pixels and G pixels, color filters of different colors are alternately aligned. Thus, of two adjacent sub-pixels, the color filter of one sub-pixel affects the light distribution characteristics of the other sub-pixel. In contrast, in the rows of the color filter corresponding to the B pixels, the color filter of the same color is integrally provided. Thus, of two adjacent sub-pixels, the color filter of one sub-pixel does not affect the light distribution characteristics of the other sub-pixel. As a result, the electro-optical device described in JP-A-2019-117941 has a problem in that a difference arises between the light distribution characteristics of the B pixels and the light distribution characteristics of the R pixels and the G pixels.

### SUMMARY

An aspect of the electro-optical device according to the present disclosure includes: a first light-emitting element including a first light-emitting region that is configured to emit light in a first wavelength range, a second light-emitting element including a second light-emitting region that is disposed at a position adjacent to the first light-emitting region in a first direction and that is configured to emit light in a second wavelength range, a third light-emitting element including a third light-emitting region that is disposed at a position adjacent to the first light-emitting region and the second light-emitting region in a second direction intersecting the first direction and that is configured to emit light in a third wavelength range, a first coloring layer that is provided overlapping the first light-emitting region in plan view and that is configured to transmit the light in the first wavelength range, a second coloring layer that is provided overlapping the second light-emitting region in plan view and that is configured to transmit the light in the second wavelength range, a third coloring layer that is provided overlapping the third light-emitting region in a plan view and that is configured to transmit the light in the third wavelength range, and a light-shielding portion including a first light-shielding portion that is provided in an island shape so as to divide the third light-emitting region into two portions along the first direction in the plan view and that is configured to block at least the light in the third wavelength range.

Another aspect of the electro-optical device according to the present disclosure includes: a first light-emitting element including a first light-emitting region that is configured to emit light in a first wavelength range, a second light-emitting element including a second light-emitting region that is disposed at a position adjacent to the first light-emitting region in a first direction and that is configured to emit light in a second wavelength range, a third light-emitting element including a third light-emitting region that is disposed at a position adjacent to the first light-emitting region in a second direction intersecting the first direction and that is configured to emit light in a third wavelength range, a fourth light-emitting element including a fourth light-emitting region that is disposed at a position adjacent to the second light-emitting region in the second direction and that is configured to emit light in a third wavelength range, a first coloring layer that is provided overlapping the first light-emitting region in a plan view and that is configured to transmit the light in the first wavelength range, a second coloring layer that is provided overlapping the second light-emitting region in the plan view and that is configured to transmit the light in the second wavelength range, a third coloring layer that is provided overlapping the third light-emitting region and the fourth light-emitting region in the plan view and that is configured to transmit the light in the third wavelength range, and a light-shielding portion including a first light-shielding portion that is provided in an island shape so as to overlap a region between the third light-emitting region and the fourth light-emitting region in the plan view and that is configured to block at least the light in the third wavelength range.

An aspect of the electronic apparatus according to the present disclosure includes: the electro-optical device according to any of the above-described aspects, and a control unit configured to control an operation of the electro-optical device.

### BRIEF DESCRIPTION OF THE DRAWINGS

FIG. 1 is a plan view schematically illustrating an electro-optical device according to a first embodiment.

FIG. 2 is an equivalent circuit diagram of a sub-pixel illustrated in FIG. 1.

FIG. 3 is a plan view illustrating a portion of an element substrate in a first embodiment.

FIG. 4 is a cross-sectional view taken along the line A-A in FIG. 3.

FIG. 5 is a cross-sectional view taken along the line B-B in FIG. 3.

FIG. 6 is a cross-sectional view taken along the line C-C in FIG. 3.

FIG. 7 is a graph illustrating a relationship between tristimulus values of light from a pixel and a visual field angle when the light-shielding portion is omitted.

FIG. 8 is a graph illustrating a relationship between tristimulus values of light from a pixel and a visual field angle when the light-shielding portion is provided.

FIG. 9 is a graph illustrating a relationship between a color difference of light from a pixel and a visual field angle.

FIG. 10 is a chromaticity diagram illustrating a color gamut of light from a pixel in the Commission Internationale de l'Eclairage (CIE) colorimetric system.

FIG. 11 is a plan view illustrating a portion of an element substrate in a second embodiment.

FIG. 12 is a plan view illustrating a portion of an element substrate in a third embodiment.

FIG. 13 is a plan view illustrating a portion of an element substrate in a fourth embodiment.

FIG. 14 is a plan view illustrating a portion of an element substrate in a fifth embodiment.

FIG. 15 is a cross-sectional view illustrating a coloring layer, a light-shielding portion, and an overcoat layer of a modified example 1.

FIG. 16 is a cross-sectional view illustrating a coloring layer, a light-shielding portion, and an overcoat layer of a modified example 2.

FIG. 17 is a cross-sectional view illustrating a coloring layer, a light-shielding portion, and an overcoat layer of a modified example 3.

FIG. 18 is a cross-sectional view illustrating a coloring layer, a light-shielding portion, and an overcoat layer of a modified example 4.

FIG. 19 is a cross-sectional view illustrating a coloring layer, a light-shielding portion, and an overcoat layer of a modified example 5.

FIG. 20 is a cross-sectional view illustrating a coloring layer, a light-shielding portion, and an overcoat layer of a modified example 6.

FIG. 21 is a cross-sectional view illustrating a coloring layer, a light-shielding portion, and an overcoat layer of a modified example 7.

FIG. 22 is a plan view illustrating a portion of an element substrate in a modified example 8.

FIG. 23 is a view schematically illustrating a virtual image display device that is an example of an electronic apparatus.

FIG. 24 is a perspective view illustrating a personal computer that is an example of an electronic apparatus.

### DESCRIPTION OF EXEMPLARY EMBODIMENTS

Hereinafter, suitable embodiments according to the present disclosure will be described with reference to the accompanying drawings. Note that, in the drawings, dimensions and scales of the parts are altered from actual dimensions and scales as appropriate, and some of the parts are schematically illustrated to make them easily recognizable. Furthermore, the scope of the present disclosure is not limited to these embodiments unless otherwise stated to limit the present disclosure in the description below.

### 1. Electro-Optical Device

### 1A. First Embodiment

### 1A-1. Overview of Electro-Optical Device

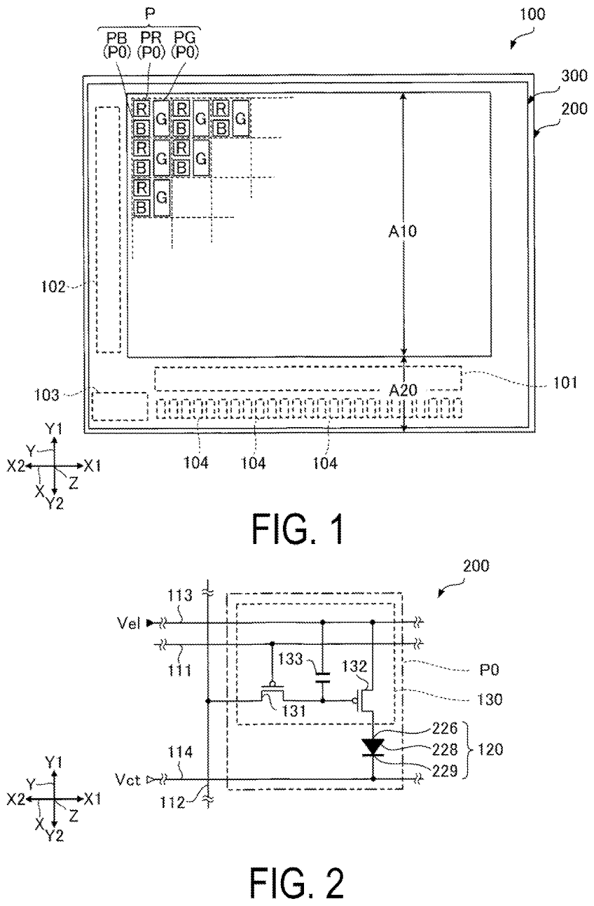

FIG. 1 is a plan view schematically illustrating an electro-optical device 100 according to a first embodiment. The electro-optical device 100 is a device that displays an image using organic EL. The electro-optical device 100 is a micro display suitably used in a head-mounted display or the like, for example.

Hereinafter, the electro-optical device 100 will be described. Note that in the description below, an X-axis, a Y-axis, and a Z-axis orthogonal to one another are used as appropriate for convenience of explanation. Furthermore, in the following, one direction along the X-axis is the X1 direction, and the direction opposite to the X1 direction is the X2 direction. Similarly, one direction along the Y-axis is the Y1 direction, and the direction opposite to the Y1 direction is the Y2 direction. One direction along the Z-axis is the Z1 direction, and the direction opposite to the Z1 direction is the Z2 direction. Here, the Y1 direction or the Y2 direction is an example of a “first direction”. The X1 direction or the X2 direction is an example of a “second direction”. Furthermore, in the following, a view in the Z1 direction or the Z2 direction may be referred to as “plan view”.

The electro-optical device 100 includes a display region A10 in which an image is displayed, and a peripheral region A20 surrounding the display region A10 in plan view. In the example illustrated in FIG. 1, the shape of the display region A10 in plan view is a quadrangle. Note that the shape of the display region A10 in plan view is not limited to the example illustrated in FIG. 1, and may be other shapes.

The display region A10 is composed of a plurality of pixels P. Each pixel P is a minimum unit in the display of an image. The plurality of pixels P are disposed in a matrix in directions along the X-axis and the Y-axis, for example. Each pixel P includes a sub-pixel PB in which light in a blue wavelength range is obtained, a sub-pixel PG in which light in a green wavelength range is obtained, and a sub-pixel PR in which light in a red wavelength range is obtained. Here, the red wavelength range is an example of a “first wavelength range”, the blue wavelength range is an example of a “second wavelength range”, and the green wavelength range is an example of a “third wavelength range”.

Note that, in the following, the sub-pixel PB, the sub-pixel PG, and the sub-pixel PR may each be referred to as sub-pixel P0 without distinction. The sub-pixel P0 is a minimum unit of which light emission is independently controllable.

As illustrated in FIG. 1, the electro-optical device 100 includes an element substrate 200, and a light transmissive substrate 300 having optical transparency. The electro-optical device 100 has a so-called top emission structure. The electro-optical device 100 emits light from the light transmissive substrate 300. Note that optical transparency refers to transparency to visible light, and means that the transmittance of visible light may be greater than or equal to 50%.

The element substrate 200 includes a data line driving circuit 101, a scanning line driving circuit 102, a control circuit 103, and a plurality of external terminals 104. The data line driving circuit 101, the scanning line driving circuit 102, the control circuit 103, and the plurality of external terminals 104 are disposed in the peripheral region A20. The data line driving circuit 101 and the scanning line driving circuit 102 are peripheral circuits that control the driving of a plurality of sub-pixels P0. The control circuit 103 controls the driving of the data line driving circuit 101 and the scanning line driving circuit 102. Image data is supplied from an upper circuit (not illustrated) to the control circuit 103. The control circuit 103 supplies various signals based on the image data to the data line driving circuit 101 and the scanning line driving circuit 102. Although not illustrated, a flexible printed circuit (FPC) substrate or the like for electrical coupling with an upper circuit is coupled to the external terminals 104. Furthermore, a power supply circuit (not illustrated) is electrically coupled to the element substrate 200.

The light transmissive substrate 300 is a cover that protects the element substrate 200 and the like. The light transmissive substrate 300 is constituted by a glass substrate or a quartz substrate, for example. The light transmissive substrate 300 is bonded to the element substrate 200 via an adhesive (not illustrated). The adhesive is a transparent adhesive that uses a resin material such as epoxy resin or acrylic resin, for example.

FIG. 2 is an equivalent circuit diagram of the sub-pixel P0 illustrated in FIG. 1. The element substrate 200 is provided with a plurality of scanning lines 111, a plurality of data lines 112, a plurality of power supplying lines 113, and a plurality of power supplying lines 114. In FIG. 2, one sub-pixel P0 and components corresponding thereto are representatively illustrated.

The scanning line 111 extends in the direction along the X-axis, while the data line 112 extends in the direction along the Y-axis. Although not illustrated, the plurality of scanning lines 111 and the plurality of data lines 112 are arranged in a lattice. Furthermore, although not illustrated, the scanning line 111 is coupled to the scanning line driving circuit 102 illustrated in FIG. 1, and the data line 112 is coupled to the data line driving circuit 101 illustrated in FIG. 1.

As illustrated in FIG. 2, the element substrate 200 includes, for each sub-pixel P0, a light-emitting element 120, and a pixel circuit 130 that supplies current to the light-emitting element 120. The light-emitting element 120 is constituted by an organic light-emitting diode (OLED). As will be described in detail later, the light-emitting element 120 includes a pixel electrode 226, a common electrode 229, and an organic layer 228 disposed therebetween.

The power supplying line 113 is electrically coupled to the pixel electrode 226 via the pixel circuit 130. On the other hand, the power supplying line 114 is electrically coupled to the common electrode 229. Here, a higher power supply potential Vel is supplied from the power supply circuit (not illustrated) to the power supplying line 113. A lower power supply potential Vct is supplied from the power supply circuit (not illustrated) to the power supplying line 114. Thus, the pixel electrode 226 functions as an anode, and the common electrode 229 functions as a cathode. In the light-emitting element 120, holes supplied from the pixel electrode 226 and electrons supplied from the common electrode 229 recombine in the organic layer 228, causing the organic layer 228 to generate light.

The pixel circuit 30 includes a switching transistor 131, a driving transistor 132, and a retention capacitor 133. The gate of the switching transistor 131 is electrically coupled to the scanning line 111. Of the source and the drain of the switching transistor 131, one is electrically coupled to the data line 112, and the other is electrically coupled to the gate of the driving transistor 132. Of the source and the drain of the driving transistor 132, one is electrically coupled to the power supplying line 113, and the other is electrically coupled to the pixel electrode 226. Of both electrodes of the retention capacitor 133, one is coupled to the gate of the driving transistor 132, and the other is coupled to the power supplying line 113.

In the pixel circuit 130 described above, when the scanning line driving circuit 102 activates the scanning signal to select a scanning line 111, a switching transistor 131 provided in the selected sub-pixel P0 is turned on. Then, data signal is supplied from the data line 112 to the driving transistor 132 corresponding to the selected scanning line 111. The driving transistor 132 supplies a current corresponding to a potential of the supplied data signal, that is, a potential difference between the gate and the source, to the light-emitting element 120. As a result, the light-emitting element 120 emits light at a luminance corresponding to the magnitude of the current supplied from the driving transistor 132. Thereafter, when the scanning line driving circuit 102 deselects the scanning line 111 to turn off the switching transistor 131, the potential of the gate of the driving transistor 132 is held by the retention capacitor 133. Thus, the light-emitting element 120 can maintain light emission even after the switching transistor 131 is turned off.

Note that the configuration of the above-described pixel circuit 130 is not limited to the illustrated configuration. For example, the pixel circuit 130 may further include a transistor that controls the conduction between the pixel electrode 226 and the driving transistor 132.

### 1A-2. Details of Element Substrate

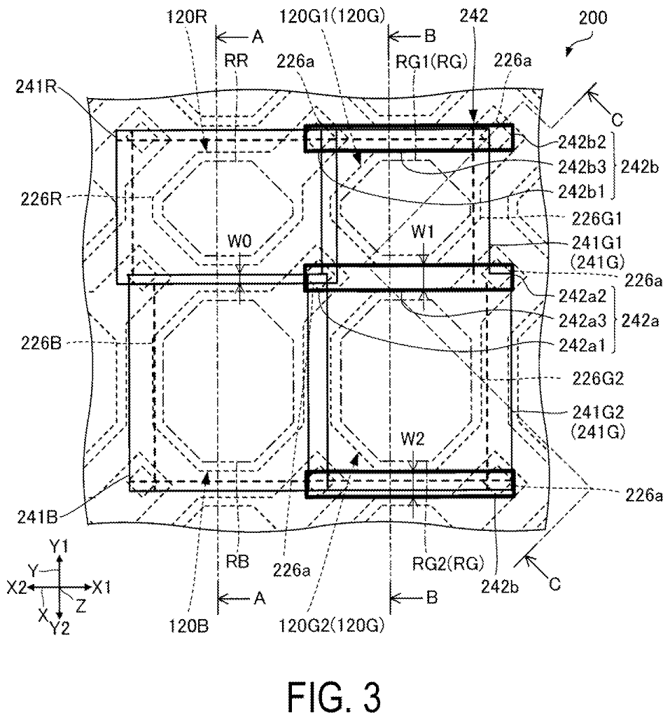

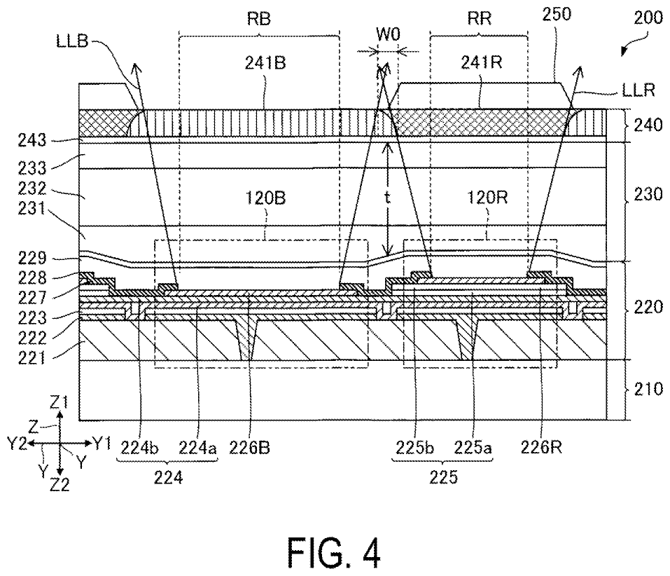

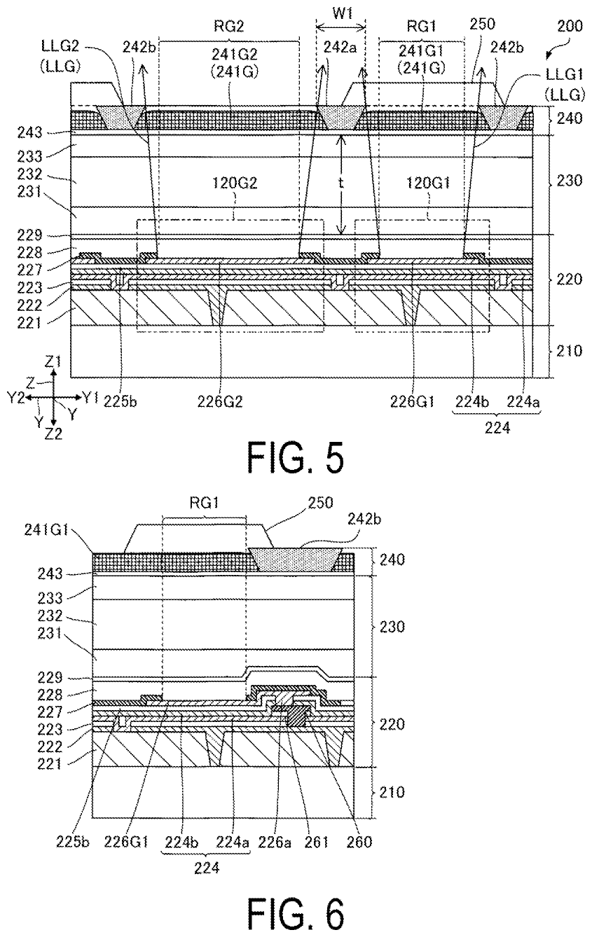

FIG. 3 is a plan view illustrating a portion of the element substrate 200 in the first embodiment. FIG. 4 is a cross-sectional view taken along the line A-A in FIG. 3. FIG. 5 is a cross-sectional view taken along the line B-B in FIG. 3. FIG. 6 is a cross-sectional view taken along the line C-C in FIG. 3. Note that in FIG. 3, of the components constituting the element substrate 200, components in one pixel P are representatively illustrated. Furthermore, in FIG. 3, illustration of an overcoat layer 250 to be described later is omitted for ease of view.

As illustrated in FIG. 3, the element substrate 200 includes, for each pixel P, a set of light-emitting elements 120R, 120G1, 120G2, and 120B. The light-emitting element 120R is a light-emitting element 120 provided in the sub-pixel PR. The light-emitting elements 120G1 and 120G2 are each a light-emitting element 120 provided in the sub-pixel PG. The light-emitting element 120B is a light-emitting element 120 provided in the sub-pixel PB.

Here, the light-emitting element 120R is an example of a “first light-emitting element”. The light-emitting element 120B is an example of a “second light-emitting element”. The light-emitting element 120G1 is an example of a “third light-emitting element”. The light-emitting element 120G2 is an example of a “fourth light-emitting element”.

However, the light-emitting elements 120G1 and 120G2 share one pixel circuit 130 for each sub-pixel PG. Therefore, the light-emitting elements 120G1 and 120G2 may be regarded as one light-emitting element 120G for each sub-pixel PG. In this case, the light-emitting element 120G for each sub-pixel PG is an example of the “third light-emitting element”. Note that the light-emitting elements 120G1 and 120G2 may each be provided with an individual pixel circuit 130.

In the present embodiment, the light-emitting elements 120R, 120G1, 120G2, and 120B are disposed in a matrix in directions along the X-axis and the Y-axis. Here, the light-emitting element 120G1 is disposed at a position in the X1 direction relative to the light-emitting element 120R, and the light-emitting element 120B is disposed at a position in the Y2 direction relative to the light-emitting element 120R. The light-emitting element 120G2 is disposed at a position in the Y2 direction relative to the light-emitting element 120G1, and in the X1 direction relative to the light-emitting element 120B.

The light-emitting element 120R includes a light-emitting region RR that is configured to emit light LLR for the sub-pixel PR. The light-emitting element 120G1 includes a light-emitting region RG1 that is configured to emit light LLG1 for the sub-pixel PG. The light-emitting element 120G2 includes a light-emitting region RG2 that is configured to emit light LLG2 for the sub-pixel PG. The light-emitting element 120B includes a light-emitting region RB that is configured to emit light LLB for the sub-pixel PB.

Here, the light LLR is light of a wavelength range including the “first wavelength range”. The light LLB is light of a wavelength range including the “second wavelength range”. The light LLG1 and LLG2 each is light of a wavelength range including the “third wavelength range”. Furthermore, the light-emitting region RR is an example of a “first light-emitting region”. The light-emitting region RB is an example of a “second light-emitting region”. The light-emitting region RG1 is an example of a “third light-emitting region”. The light-emitting region RG2 is an example of a “fourth light-emitting region”. Note that the light-emitting regions RG1 and RG2 may be regarded as one light-emitting region RG for each sub-pixel PG. In this case, the light-emitting regions RG1 and RG2 for each sub-pixel PG are an example of the “third light-emitting region”.

In the example illustrated in FIG. 3, each of the light-emitting regions RR, RG1, RG2, and RB forms an octagon in plan view. The area of the light-emitting region RR is smaller than the area of each of the light-emitting regions RB and RG. Furthermore, the area of the light-emitting region RR is equal to the area of the light-emitting region RG1. Furthermore, the area of the light-emitting region RB is equal to the area of the light-emitting region RG2. Here, the area of the light-emitting region RR is smaller than the sum of the area of the light-emitting regions RG1 and RG2. In other words, the area of the light-emitting region RR is smaller than the area of the light-emitting region RG. Here, the “area” of these regions refers to the area in plan view. Note that the area of the light-emitting region RR may be different from the area of the light-emitting region RG1. Furthermore, the shape of each of the light-emitting regions RR, RG1, RG2, and RB is not limited to an octagon, and may be other shapes. Furthermore, the shapes of the light-emitting regions RR, RG1, RG2, and RB in plan view may be different from one another.

As illustrated in FIGS. 4 and 5, the element substrate 200 includes a substrate 210, a light-emitting element layer 220, a sealing layer 230, a color filter 240, and an overcoat layer 250. These layers are stacked in the Z1 direction in this order. Note that the layers constituting the element substrate 200 are formed by using a known film formation method as appropriate.

The substrate 210 is, for example, a silicon substrate. Although not illustrated, the above-described pixel circuit 130 and various wiring coupled thereto are formed in the substrate 210. Note that the substrate 210 is not limited to a silicon substrate, and may be, for example, a glass substrate, a resin substrate, or a ceramic substrate. In the present embodiment, since the electro-optical device 100 is a top emission type, the substrate 210 need not have optical transparency. Each of the above-described transistors included in the pixel circuit 130 may be any of a MOS type transistor, a thin film transistor, or an electric field effect transistor. When the transistor included in the pixel circuit 130 is a MOS type transistor including an active layer, the active layer may be constituted by a silicon substrate. Furthermore, examples of the material for the parts and various wiring that constitute the pixel circuit 130 include conductive materials such as polysilicon, metals, metal silicides, and metallic compounds.

The light-emitting element layer 220 is a layer on which the light-emitting elements 120R, 120G1, 120G2, and 120B are provided. Specifically, the light-emitting element layer 220 includes an insulating layer 221, a reflection layer 222, a reflection increasing layer 223, an insulating layer 224, a distance adjustment layer 225, a plurality of pixel electrodes 226R, 226G1, 226G2, and 226B, an element isolation layer 227, an organic layer 228, and the common electrode 229. These layers are stacked in the Z1 direction in this order.

The insulating layer 221 is an interlayer insulating film disposed between the substrate 210 and the reflection layer 222. The insulating layer 221 is formed of an insulating material such as silicon oxide (SiO₂), for example.

The reflection layer 222 is a layer having light reflectivity that reflects light generated at the organic layer 228 in the Z1 direction. Although not illustrated, the reflection layer 222 is split into a plurality of portions disposed in a matrix corresponding to the plurality of sub-pixels P0 in plan view. Examples of the constituent material for the reflection layer 222 include metals such as aluminum (Al), silver (Ag), copper (Cu), and titanium (Ti), or alloys of any of these metals. For example, the reflection layer 222 is constituted by a laminate of a film formed of Ti and a film formed of an alloy containing Al and Cu. In the example illustrated in FIGS. 4 and 5, the reflection layer 222 also functions as wiring. Although not illustrated, the wiring is electrically coupled to the above-described pixel circuit 130, for example. Note that the reflection layer 222 need not function as the wiring. In this case, wiring is provided separately from the reflection layer 222. Furthermore, light reflectivity refers to reflectivity to visible light, and means that the reflectance of visible light may be greater than or equal to 50%.

The reflection increasing layer 223 is a layer having optical transparency and insulating properties for enhancing light reflectivity of the reflection layer 222. The reflection increasing layer 223 is disposed across the entire reflection layer 222 in plan view. The reflection increasing layer 223 is constituted by a silicon oxide film, for example.

The insulating layer 224 includes a first insulating layer 224a and a second insulating layer 224b. The first insulating layer 224a fills gaps between a plurality of split portions of the reflection layer 222 and the reflection increasing layer 223, and is disposed across the entire reflection increasing layer 223. The second insulating layer 224b is disposed across the entire first insulating layer 224a. Each of the first insulating layer 224a and the second insulating layer 224b is constituted by a silicon nitride (SiN) film, for example.

The distance adjustment layer 225 is a layer having optical transparency and insulating properties for adjusting the distance between the reflection layer 222 and the common electrode 229 for each sub-pixel P0. The distance adjustment layer 225 includes a first distance adjustment layer 225a and a second distance adjustment layer 225b. Each of the first distance adjustment layer 225a and the second distance adjustment layer 225b, for example,

Of the sub-pixels PR, PG, and PB, the first distance adjustment layer 225a is disposed in the sub-pixel PR, and is disposed neither in the sub-pixel PG nor PB. Of the sub-pixels PR, PG, and PB, the second distance adjustment layer 225b is disposed in the sub-pixels PR and PG, and is not disposed in the sub-pixel PB. Therefore, the first distance adjustment layer 225a and the second distance adjustment layer 225b are disposed in the sub-pixel PR. Of the first distance adjustment layer 225a and the second distance adjustment layer 225b, the second distance adjustment layer 225b is disposed in the sub-pixel PG. Neither the first distance adjustment layer 225a nor the second distance adjustment layer 225b is disposed in the sub-pixel PB.

Each of the pixel electrodes 226R, 226G1, 226G2, and 226B is provided for each sub-pixel P0, and is a layer having conductivity and optical transparency. However, the pixel electrodes 226G1 and 226G2 are shared in the sub-pixel PG. Examples of the constituent material for each of the pixel electrodes 226R, 226G1, 226G2, and 226B include transparent conductive materials such as indium tin oxide (ITO) and indium zinc oxide (IZO).

The pixel electrode 226R is a pixel electrode 226 provided in the sub-pixel PR. The pixel electrodes 226G1 and 226G2 are pixel electrodes 226 provided in the sub-pixel PG. The pixel electrode 226B is a pixel electrode 226 provided in the sub-pixel PB. Note that the pixel electrode 226R is an example of a “first pixel electrode”. The pixel electrode 226B is an example of a “second pixel electrode”. The pixel electrode 226G1 is an example of a “third pixel electrode”. The pixel electrode 226G2 is an example of a “fourth pixel electrode”.

The element isolation layer 227 is a layer having insulating properties that covers the respective outer edges of the pixel electrodes 226R, 226G1, 226G2, and 226B. The element isolation layer 227 is formed of an insulating material such as silicon oxide, for example. A plurality of openings for bringing predetermined regions of the pixel electrodes 226R, 226G1, 226G2, and 226B into contact with the organic layer 228 are provided in the element isolation layer 227. The plurality of openings define the light-emitting regions RR, RG1, RG2, and RB.

Here, the region in which the pixel electrode 226R and the organic layer 228 come into contact with each other is equal to the light-emitting region RR in plan view. Similarly, the region in which the pixel electrode 226G1 and the organic layer 228 come into contact with each other is equal to the light-emitting region RG1 in plan view. The region in which the pixel electrode 226G2 and the organic layer 228 come into contact with each other is equal to the light-emitting region RG2 in plan view. The region in which the pixel electrode 226B and the organic layer 228 come into contact with each other is equal to the light-emitting region RB in plan view.

The organic layer 228 is a layer formed of an organic compound as main material. Specifically, the organic layer 228 includes a light-emitting layer that emits light by energization. In the present embodiment, the light-emitting layer includes, for example, a light-emitting layer whereby a red luminescent color is obtained, a light-emitting layer whereby a green luminescent color is obtained, and a light-emitting layer whereby a blue luminescent color is obtained, and these are stacked as appropriate. Thus, light emission of white or a color similar to white is realized in the organic layer 228. Note that a known configuration and material is applicable to the organic layer 228. Although not illustrated, the organic layer 228 includes, apart from a light-emitting layer, a hole injection layer, a hole transport layer, an electron transport layer, an electron injection layer, or the like as appropriate and as necessary. Furthermore, the organic layer 228 may include a layer formed of an inorganic material such as a metal as necessary.

The common electrode 229 is provided common to the sub-pixels PR, PG, and PB, and is a layer having light reflectivity, optical transparency, and conductivity. Examples of the constituent material for the common electrode 229 include alloys containing Ag such as MgAg.

In the light-emitting element layer 220 described above, the light-emitting element 120R includes the insulating layer 221, the reflection layer 222, the reflection increasing layer 223, the insulating layer 224, the first distance adjustment layer 225a, the second distance adjustment layer 225b, the pixel electrode 226R, the element isolation layer 227, the organic layer 228, and the common electrode 229. The light-emitting element 120G1 has a layer configuration similar to that of the light-emitting element 120R except that the first distance adjustment layer 225a is omitted and the pixel electrode 226G1 is included instead of the pixel electrode 226R. The light-emitting element 120G2 has a layer configuration similar to that of the light-emitting element 120R except that the first distance adjustment layer 225a is omitted and the pixel electrode 226G2 is included instead of the pixel electrode 226R. The light-emitting element 120B has a layer configuration similar to that of the light-emitting element 120R except that the first distance adjustment layer 225a and the second distance adjustment layer 225b are omitted and the pixel electrode 226B is included instead of the pixel electrode 226R.

Here, the distance between the reflection layer 222 and the common electrode 229 is different for each sub-pixel P0. Specifically, the distance in the sub-pixel PR is set so as to correspond to the red wavelength range. The distance in the sub-pixel PG is set so as to correspond to the green wavelength range. The distance in the sub-pixel PB is set so as to correspond to the blue wavelength range.

Thus, in the sub-pixel PR, an optical resonance structure is realized in which light having a red wavelength resonates between the reflection layer 222 and the common electrode 229. In the sub-pixel PG, an optical resonance structure is realized in which light having a green wavelength resonates between the reflection layer 222 and the common electrode 229. In the sub-pixel PB, an optical resonance structure is realized in which light having a blue wavelength resonates between the reflection layer 222 and the common electrode 229.

The resonant wavelength in the above-described optical resonance structure is determined by the distance between the reflection layer 222 and the common electrode 229. When the distance is L0, and the resonant wavelength is λ0, the following relationship equation [1] holds true. Note that the ϕ (radian) in the relationship equation [1] represents the sum of the phase shifts that occur during transmission and reflection between the reflection layer 222 and the common electrode 229.

{(2×L0)/λ0+ϕ}/(2π)=m0 (where m0 is an integer) [1]

The distance L0 is set such that a peak wavelength of light in a wavelength range to be extracted is at a wavelength λ0. This setting augments light in a predetermined wavelength range to be extracted, and makes it possible to increase intensity of the light and narrow the spectrum.

As described above, in the present embodiment, the distance L0 is adjusted by varying the thickness of the distance adjustment layer 225 for each sub-pixel P0. Note that the method of adjusting the distance L0 is not limited to the method of adjusting by the thickness of the distance adjustment layer 225. For example, the distance L0 may be adjusted by varying the thickness of the pixel electrode 226 for each sub-pixel PB, PG, and PR.

The sealing layer 230 is a layer that has gas barrier properties for sealing the light-emitting element layer 220 so as to protect it from external moisture, oxygen, or the like, and that has optical transparency. Specifically, the sealing layer 230 includes a first layer 231, a second layer 232, and a third layer 233. These layers are stacked in the Z1 direction in this order. Each of the first layer 231 and the third layer 233 is a layer having optical transparency for enhancing gas barrier properties. Each of the first layer 231 and the third layer 233 is constituted by a silicon oxynitride (SiON) film, for example. The second layer 232 is a layer having optical transparency for providing a flat surface to the third layer 233. The second layer 232 is formed of a resin material such as epoxy resin, for example.

The color filter 240 is a layer that selectively transmits, of the light from the light-emitting element 120, light in a predetermined wavelength range. Compared to a case in which the color filter 240 is not used, using the color filter 240 makes it possible to enhance color purity in a desired color of the light emitted from each sub-pixel P0.

Specifically, the color filter 240 includes coloring layers 241R, 241G, and 241B, a light-shielding portion 242, and an adhesion layer 243. Here, the coloring layer 241R is an example of a “first coloring layer”. The coloring layer 241B is an example of a “second coloring layer”. The coloring layer 241G is an example of a “third coloring layer”.

The coloring layer 241R is provided in the sub-pixel PR. The coloring layer 241R is a filter that selectively transmits, of the light from the light-emitting element 120R, light in a red wavelength range. The coloring layer 241G is provided in the sub-pixel PG. The coloring layer 241G is a filter that selectively transmits, of the light from the light-emitting elements 120G1 and 120G2, light in a green wavelength range. The coloring layer 241B is provided in the sub-pixel PB. The coloring layer 241B is a filter that selectively transmits, of the light from the light-emitting element 120B, light in a blue wavelength range. The coloring layers 241R, 241G, and 241B are formed of, for example, a resin material such as an acrylic photosensitive resin material containing a color material such as pigment or dye of a corresponding color.

As illustrated in FIG. 3, the coloring layers 241R, 241G, and 241B are each disposed overlapping a light-emitting region of the light-emitting element 120 that is configured to emit light in the corresponding wavelength range in plan view. Therefore, the coloring layer 241R and the coloring layer 241B are aligned in the direction along the Y-axis. The coloring layer 241R and the coloring layer 241G are aligned in the direction along the X-axis. The coloring layer 241B and the coloring layer 241G are aligned in the direction along the X-axis. Here, the coloring layer 241R forms a rectangle having a long side along the X-axis in plan view. The coloring layer 241B forms a rectangle having a long side along the Y-axis in plan view. The coloring layer 241G has a shape extending in the direction along the Y-axis in plan view. More specifically, the coloring layer 241G includes a coloring layer 241G1 and a coloring layer 241G2 having a different length along the X-axis, and these are aligned in the direction along the Y-axis. Here, the coloring layer 241G1 is located in the X1 direction relative to the coloring layer 241R. The coloring layer 241G2 is located in the X1 direction relative to the coloring layer 241B.

In the present embodiment, the thicknesses of the coloring layers 241R and 241B are equal to each other. Furthermore, the thickness of the coloring layer 241G is thinner than the thickness of the coloring layer 241R or 241B.

Note that the shapes, sizes, and the like of the coloring layers 241R, 241G, and 241B are not limited to the example illustrated in FIG. 3. For example, the planar shapes or sizes of the coloring layers 241R and 241B may be equal to each other. Furthermore, the planar shape of the coloring layer 241G may be a simple rectangle. Furthermore, the thicknesses of the coloring layers 241R, 241G, and 241B are not limited to the examples illustrated in FIGS. 4 and 5, and may be any thickness. For example, as illustrated in FIG. 15 or 19 to be described later, the thicknesses of the coloring layers 241R and 241G may be different from each other.

The light-shielding portion 242 is a layer having light-shielding properties that is provided in an island shape so as to divide the coloring layer 241G into a plurality of portions aligned in the direction along the Y-axis in plan view. The light-shielding portion 242 is formed of, for example, a resin material such as an acrylic photosensitive resin material containing a color material such as pigment or dye. It is only required that the color material is such that the color of the light-shielding portion 242 differs from the color of the coloring layer 241G. However, from the viewpoint of enhancing light-shielding properties against the light from the light-emitting element 120G, the color material may be such that the color of the light-shielding portion 242 becomes black or assumes a dark color close to black. Examples of the color material that causes the color of the light-shielding portion 242 to become black or assume a dark color close to black include color materials of black such as carbon black, and color materials obtained by mixing color materials of a plurality of colors such as red, blue, and green.

The light-shielding portion 242 may be formed of a material separate from that of the above-described coloring layers 241R, 241G, and 241B. From the viewpoint of reducing cost and the like, however, the light-shielding portion 242 may be formed of the same material as that of the coloring layers 241R, 241G, and 241B. In this case, the light-shielding portion 242 may be formed of a material obtained by mixing the constituent materials of the coloring layers 241R, 241G, and 241B, or may be constituted by a stack of the coloring layer 241R, the coloring layer 241B, and the coloring layer 241G. When the light-shielding portion 242 is constituted by such stack, for example, the forming step for the coloring layers 241R, 241G, and 241B is used to collectively form the light-shielding portion 242 with these layers. Note that in the present embodiment, as illustrated in FIG. 5, the thickness of the light-shielding portion 242 is equal to the thickness of the coloring layer 241R or 241B. However, the thickness of the light-shielding portion 242 is not limited thereto, and may be different from the thickness of the coloring layer 241R or 241B, as illustrated in FIG. 15 or 19 to be described later, for example.

In the present embodiment, the light-shielding portion 242 includes a plurality of first light-shielding portions 242a and a plurality of second light-shielding portions 242b.

As illustrated in FIG. 3, in plan view, the first light-shielding portion 242a overlaps the region between the light-emitting region RG1 and the light-emitting region RG2 that are adjacent to each other in the same pixel P, and a contact portion 226a to be described later of each of the light-emitting elements 120B and 120G2. Here, in plan view, this region divides the coloring layer 241G into two portions adjacent to each other in the direction along the Y-axis. In the example illustrated in FIG. 3, the two portions are the coloring layer 241G1 and the coloring layer 241G2 described above.

Here, the contact portion 226a will be described with reference to FIG. 6. As illustrated in FIG. 6, a relay electrode 260 is disposed between the first insulating layer 224a and the second insulating layer 224b of the insulating layer 224. The pixel electrode 226 includes the contact portion 226a that penetrates the distance adjustment layer 225 and that is coupled to the relay electrode 260. The relay electrode 260 is an electrode for electrically coupling the pixel electrode 226 to the pixel circuit 130. The relay electrode 260 is electrically coupled to the reflection layer 222. The relay electrode 260 is provided for each light-emitting element 120. The relay electrode 260 is disposed at a position that does not overlap the light-emitting regions RR, RG1, RG2, and RB in plan view. Examples of the constituent material for the relay electrode 260 include conductive materials such as tungsten (W), titanium (Ti), and titanium nitride (TiN).

In the example illustrated in FIG. 6, an insulating layer 261 is disposed between the relay electrode 260 and the first insulating layer 224a. The relay electrode 260 penetrates the insulating layer 261 and the first insulating layer 224a and is coupled to the reflection layer 222. The insulating layer 261 is constituted by a silicon oxide film, for example. Note that in FIG. 6, the pixel electrode 226 and the relay electrode 260 of the light-emitting element 120G1 are representatively illustrated. However, the pixel electrodes 226 and the relay electrodes 260 of the light-emitting elements 120R, 120G2, and 120B are configured in a manner similar to the pixel electrode 226 and the relay electrode 260 of the light-emitting element 120G1.

Here, the relay electrode 260 corresponding to the light-emitting element 120R is an example of a “first relay electrode”. The relay electrode 260 corresponding to the light-emitting element 120B is an example of a “second relay electrode”. The relay electrode 260 corresponding to the light-emitting element 120G1 is an example of a “third relay electrode”. The relay electrode 260 corresponding to the light-emitting element 120G2 is an example of a “fourth relay electrode”. The contact portion 226a provided in the pixel electrode 226 of the light-emitting element 120R is an example of a “first contact portion”. The contact portion 226a provided in the pixel electrode 226 of the light-emitting element 120B is an example of a “second contact portion”. The contact portion 226a provided in the pixel electrode 226 of the light-emitting element 120G1 is an example of a “third contact portion”. The contact portion 226a provided in the pixel electrode 226 of light-emitting element 120G2 is an example of a “fourth contact portion”.

In such a configuration in which the relay electrode 260 is provided as described above, the thickness of the organic layer 228 tends to be thin near the contact portion 226a. Thus, when the light-emitting element 120 is driven at low current, in each of the light-emitting regions, a portion near the contact portion 226a tends to preferentially emit light compared to the central portion. Such light emission near the contact portion 226a causes resonance at a frequency different from the intended resonance frequency in the above-described optical resonance structure, thus causing color shift. Therefore, such light emission may be blocked by the light-shielding portion 242.

In the present embodiment, as illustrated in FIG. 3, the width W1 of the first light-shielding portion 242a in the direction along the Y-axis is constant across the entire length in the direction along the X-axis. Here, the width W1 is larger than the overlapping width W0 between the coloring layer 241R and the coloring layer 241B, and is smaller than the distance L1 between the light-emitting region RG1 and the light-emitting region RG2.

Furthermore, in the present embodiment, as illustrated in FIG. 5, when viewed in a cross section orthogonal to the Y-axis, the first light-shielding portion 242a forms a trapezoid of which the width is increasingly reduced toward the Z2 direction. Thus, the visual field angle of the sub-pixel PG can be increased, while the light emission near the contact portion 226a described above is suitably blocked by the first light-shielding portion 242a. The first light-shielding portion 242a having such a cross-sectional shape is formed, for example, by using a negative photosensitive resin material as constituent material. Note that the cross-sectional shape of the first light-shielding portion 242a is not limited to the example illustrated in FIG. 5. For example, the cross-sectional shape of the first light-shielding portion 242a may be a rectangle, or may be a trapezoid of which the width is increasingly reduced toward the Z1 direction as illustrated in FIGS. 18 to 21 to be described later.

On the other hand, the second light-shielding portion 242b is configured in a manner similar to that of the first light-shielding portion 242a except that it is differently disposed. Here, in plan view, the second light-shielding portion 242b overlaps the region between the light-emitting region RG1 and the light-emitting region RG2 that are in different pixels P and are adjacent to each other, and the respective contact portions 226a of the light-emitting elements 120R and 120G1.

In the example illustrated in FIG. 3, the planar shapes and sizes of the first light-shielding portion 242a and the second light-shielding portion 242b are the same as each other. Note that the planar shapes and sizes of the first light-shielding portion 242a and the second light-shielding portion 242b may be different from each other.

The coloring layers 241R, 241G, 241B, and the light-shielding portion 242 described above are bonded to the above-described sealing layer 230 via the adhesion layer 243. The adhesion layer 243 is a layer having optical transparency for enhancing the adhesion between the color filter 240 and the sealing layer 230. The adhesion layer 243 is formed of a resin material such as epoxy resin, for example. Note that the thickness of the adhesion layer 243 is not particularly limited, and may be any thickness.

The overcoat layer 250 is partially disposed on the color filter 240 described above. The overcoat layer 250 is a layer having optical transparency that is provided overlapping the coloring layers 241R and 241G1 so as not to overlap the coloring layers 241B and 241G2 in plan view, and that forms a plurality of bands extending in the direction along the X-axis. However, the overcoat layer 250 overlaps the boundary between the coloring layers 241B and 241G2 and the coloring layers 241R and 241G1, or the vicinity of the boundary in plan view. The overcoat layer 250 is substantially colorless. For example, the overcoat layer 250 is formed of a resin material such as an acrylic photosensitive resin material that contains no color material.

Providing such an overcoat layer 250 causes a plurality of grooves due to the overcoat layer 250 to be formed extending in the direction along the X-axis on the surface facing the Z1 direction of the color filter 240. When the element substrate 200 and the light transmissive substrate 300 are bonded to each other with an adhesive, the plurality of grooves have an effect of smoothly spreading the adhesive in the direction along the X-axis. This effect reduces air bubbles or the like mixed into the layer by the adhesive, and allows these substrates to be suitably adhered.

Note that the overcoat layer 250 may be provided overlapping the coloring layers 241B and 241G2 so as not to overlap the coloring layers 241R and 241G1 in plan view. Furthermore, the overcoat layer 250 is not limited to an aspect of extending in the direction along the Y-axis, and may have an aspect of extending in the direction along the X-axis. In this case, for example, the overcoat layer 250 is provided overlapping the coloring layers 241G1 and 241G2 so as not to overlap the coloring layers 241R and 241B, or is provided overlapping the coloring layers 241R and 241B so as not to overlap the coloring layers 241G1 and 241G2.

### 1A-3. Effect of Light-Shielding Portion 242

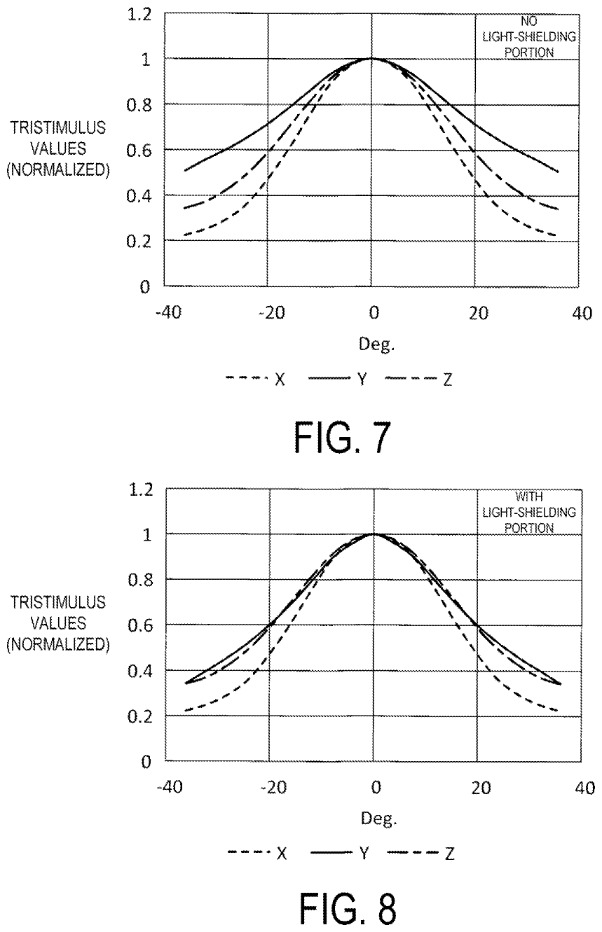

FIG. 7 is a graph illustrating a relationship between tristimulus values of light from a pixel P and a visual field angle when the light-shielding portion 242 is omitted. FIG. 8 is a graph illustrating a relationship between tristimulus values of light from a pixel P and a visual field angle when the light-shielding portion 242 is provided. The horizontal axes in FIGS. 7 and 8 represent, with the normal line direction of the display surface of the electro-optical device 100 as a reference, a visual field angle that is an angle formed by the observation direction and the normal direction when the viewpoint is changed along the X-axis. The vertical axes in FIGS. 7 and 8 represent normalized values for each of the X values, the Y values, and the Z values of tristimulus values, with the value when the angle is at 0 degree being 1. In FIGS. 7 and 8, X values are indicated by dashed lines, Y values are indicated by solid lines, and Z values are indicated by dot-dash lines.

As illustrated in FIG. 7, when the light-shielding portion 242 is omitted, the greater the visual field angle, the greater the difference between the Y value and the X value or the Z value, in particular, the difference between the Y value and the Z value. Therefore, when the light-shielding portion 242 is omitted, color shift due to changes in the visual field angle is increased. This is because one of the coloring layers 241R and 241B adjacent to each other affects the light distribution characteristics of the light from a light-emitting region corresponding to the other, while one of the coloring layers 241G1 and 241G2 adjacent to each other does not affect the light distribution characteristics of the light from a light-emitting region corresponding to the other. The greater the ratio of the thickness t of the sealing layer 230 to the distance between the light-emitting regions, the more prominent such a difference in light distribution characteristics between the sub-pixel PR and PB and the sub-pixel PG.

In contrast, as illustrated in FIG. 8, when the light-shielding portion 242 is provided, even if the visual field angle is large, the difference between the Y value and the X value or the Z value can be reduced more than when the light-shielding portion 242 is omitted. In the example illustrated in FIG. 8, even when the visual field angle is increased, the difference between the Y value and the Z value barely changes. This is because when the visual field angle is increased, the light-shielding portion 242 blocks light from the light-emitting region RG1 or RG2, just like one of the coloring layers 241R and 241B blocks light from the light-emitting region corresponding to the other. Therefore, providing the light-shielding portion 242 can reduce color shift due to changes in the visual field angle.

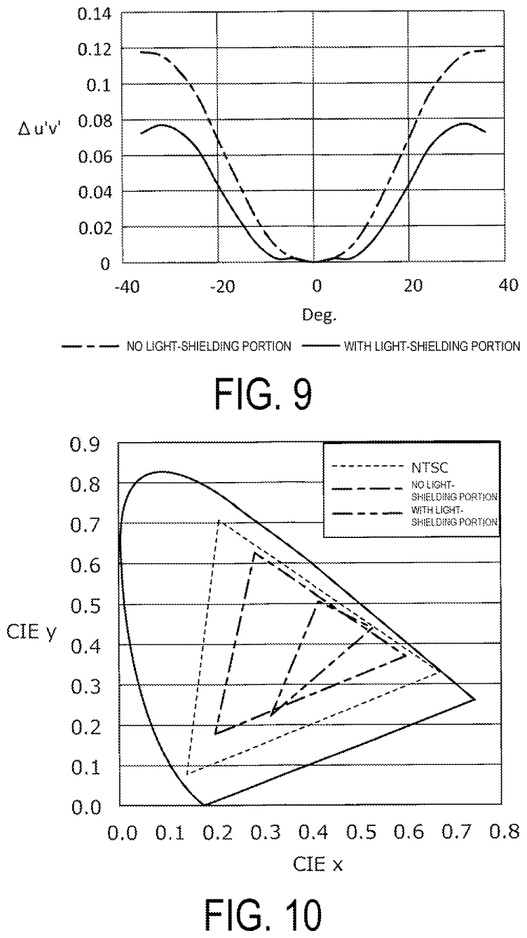

FIG. 9 is a graph illustrating a relationship between a color difference of light from a pixel P and a visual field angle. Similar to the horizontal axes in FIGS. 7 and 8 described above, the horizontal axis in FIG. 9 represents the visual field angle. The vertical axis in FIG. 9 represents a color difference from the display color in a reference observation direction when the electro-optical device 100 is caused to emit white light. In FIG. 9, a case in which the light-shielding portion 242 is omitted is indicated by a dot-dash line, and a case in which the light-shielding portion 242 is provided is indicated by a solid line.

As illustrated in FIG. 9, when the light-shielding portion 242 is provided, even if the visual field angle is large, the color difference can be reduced more than when the light-shielding portion 242 is omitted. This is because when the visual field angle is increased, the light-shielding portion 242 blocks light from the light-emitting region RG1 or RG2, just like one of the coloring layers 241R and 241B blocks light from the light-emitting region corresponding to the other. Therefore, providing the light-shielding portion 242 can enhance the visual field angle characteristics.

FIG. 10 is a chromaticity diagram illustrating a color gamut of light from a pixel P in the CIE colorimetric system. In FIG. 10, the color gamut of the CIE colorimetric system is indicated by a solid line, the color gamut defined by the National Television System Committee (NTSC) standards is indicated by a dashed line, the color gamut when the light-shielding portion 242 is omitted is indicated by a two-dot-dash line, and the color gamut when the light-shielding portion 242 is provided is indicated by a dot-dash line.

As illustrated in FIG. 10, when the light-shielding portion 242 is provided, even if the visual field angle is large, the color gamut can be enlarged more than when the light-shielding portion 242 is omitted. This is because unintended light emission near the contact portion 226a is blocked by the light-shielding portion 242.

### 1A-4. Summary of First Embodiment

As described above, the electro-optical device 100 described above includes the light-emitting element 120R that is an example of the “first light-emitting element”, the light-emitting element 120B that is an example of the “second light-emitting element”, the light-emitting element 120G1 that is an example of the “third light-emitting element”, the light-emitting element 120G2 that is an example of the “fourth light-emitting element”, the coloring layer 241R that is an example of the “first coloring layer”, the coloring layer 241B that is an example of the “second coloring layer”, the coloring layer 241G that is an example of the “third coloring layer”, and the light-shielding portion 242.

Here, the light-emitting element 120R includes the light-emitting region RR that is an example of the “first light-emitting region”. The light-emitting region RR emits the light LLR in the first wavelength range. The light-emitting element 120B includes the light-emitting region RB that is an example of the “second light-emitting region”. The light-emitting region RB is disposed at a position adjacent to the light-emitting region RR in the Y2 direction that is an example of the “first direction”, and emits the light LLB in the second wavelength range different from the first wavelength range. The light-emitting element 120G1 includes the light-emitting region RG1 that is an example of the “third light-emitting region”. The light-emitting region RG1 is disposed at a position adjacent to the light-emitting region RR in the X1 direction that is an example of the “second direction intersecting the first direction”, and emits light LLG in the third wavelength range different from each of the first wavelength range and the second wavelength range. The light-emitting element 120G2 includes the light-emitting region RG2 that is an example of the “fourth light-emitting region”. The light-emitting region RG2 is disposed at a position adjacent to the light-emitting region RB in the X1 direction, and emits the light LLG in the third wavelength range.

The coloring layer 241R is provided overlapping the light-emitting region RR in plan view, and transmits the light LLR in the first wavelength range. The coloring layer 241B is provided overlapping the light-emitting region RB in plan view, and transmits the light LLB in the second wavelength range. The coloring layer 241G is provided overlapping the light-emitting region RG1 and the light-emitting region RG2 in plan view, and transmits the light LLG in the third wavelength range.

In addition, the light-shielding portion 242 includes the first light-shielding portion 242a. The first light-shielding portion 242a is provided in an island shape so as to overlap the region between the light-emitting region RG1 and the light-emitting region RG2 in plan view, and blocks at least the light LLG in the third wavelength range. Here, the first light-shielding portion 242a is provided in an island shape so as to divide the coloring layer 241G into two portions aligned in the Y2 direction in plan view. Note that the aggregate of the light-emitting region RG1 and the light-emitting region RG2 may be regarded as one light-emitting region RG, and the aggregate of the light-emitting elements 120G1 and 120G2 may be regarded as one light-emitting element 120G. In this case, the light-emitting element 120G is an example of the “third light-emitting element”, and the light-emitting region RG is an example of the “third light-emitting region”. Here, the first light-shielding portion 242a is provided in an island shape so as to divide the light-emitting region RG into two portions aligned in the Y2 direction in plan view.

In the electro-optical device 100 described above, the first light-shielding portion 242a overlaps the region between the light-emitting region RG1 and the light-emitting region RG2 in plan view, so the difference between the light distribution characteristics of the light emitted from the light-emitting region RG1 and the light-emitting region RG2 and the light distribution characteristics of the light emitted from the light-emitting region RR and the light-emitting region RB can be reduced.

Furthermore, as described above, the electro-optical device 100 includes the relay electrode 260 included in the light-emitting element 120R as the “first relay electrode”, the relay electrode 260 included in the light-emitting element 120B as the “second relay electrode”, the relay electrode 260 included in the light-emitting element 120G1 as the “third relay electrode”, the relay electrode 260 included in the light-emitting element 120G2 as the “fourth relay electrode”, and the insulating layer 261.

Here, the light-emitting element 120R includes the pixel electrode 226R that is an example of the “first pixel electrode”. The relay electrode 260 as the “first relay electrode” is electrically coupled to the pixel electrode 226R. The light-emitting element 120B includes the pixel electrode 226B that is an example of the “second pixel electrode”. The relay electrode 260 as the “second relay electrode” is electrically coupled to the pixel electrode 226B. The light-emitting element 120G1 includes the pixel electrode 226G1 that is an example of the “third pixel electrode”. The relay electrode 260 as the “third relay electrode” is electrically coupled to the pixel electrode 226G1. The light-emitting element 120G2 includes the pixel electrode 226G2 that is an example of the “fourth pixel electrode”. The relay electrode 260 as the “fourth relay electrode” is electrically coupled to the pixel electrode 226G2. The insulating layer 261 is provided between the pixel electrode 226R and the relay electrode 260 as the first relay electrode, between the pixel electrode 226B and the relay electrode 260 as the second relay electrode, between the pixel electrode 226G1 and the relay electrode 260 as the third relay electrode, and between the pixel electrode 226G2 and the relay electrode 260 as the fourth relay electrode.

Furthermore, the pixel electrode 226R includes the contact portion 226a as the first contact portion that penetrates the insulating layer 261 and that is electrically coupled to the relay electrode 260 as the first relay electrode. The pixel electrode 226B includes the contact portion 226a as the second contact portion that penetrates the insulating layer 261 and that is electrically coupled to the relay electrode 260 as the second relay electrode. The pixel electrode 226G1 includes the contact portion 226a as the third contact portion that penetrates the insulating layer 261 and that is electrically coupled to the relay electrode 260 as the third relay electrode. The pixel electrode 226G2 includes the contact portion 226a as the fourth contact portion that penetrates the insulating layer 261 and that is electrically coupled to the relay electrode 260 as the fourth relay electrode.

In addition, the first light-shielding portion 242a overlaps the contact portion 226a as the first contact portion or the second contact portion, and the contact portion 226a as the third contact portion or the fourth contact portion in plan view. Thus, light emission in the vicinity of the respective contact portions 226a of the light-emitting element 120B and the light-emitting element 120G2 can be blocked by the first light-shielding portion 242a. As a result, it is possible to suppress degradation in color gamut due to the light emission.

Note that depending on the disposition of the contact portions 226a, the first light-shielding portion 242a may overlap each of the contact portion 226a of the light-emitting element 120R and the contact portion 226a of the light-emitting element 120G1 in plan view. In this case, light emission in the vicinity of the respective contact portions 226a of the light-emitting element 120R and the light-emitting element 120G1 can be blocked by the first light-shielding portion 242a.

Furthermore, as described above, the light-shielding portion 242 overlaps the respective contact portions 226a of the light-emitting element 120R, the light-emitting element 120B, the light-emitting element 120G1, and the light-emitting element 120G2 in plan view. Thus, light emission in the vicinity of the respective contact portions 226a of the light-emitting element 120R, the light-emitting element 120B, the light-emitting element 120G1, and the light-emitting element 120G2 can be blocked by the light-shielding portion 242. As a result, it is possible to suitably suppress degradation in color gamut due to the light emission.

Specifically, as described above, the light-shielding portion 242 further includes a second light-shielding portion 242b overlapping the respective contact portions 226a of the light-emitting element 120R and the light-emitting element 120G1 in plan view.

Here, the first light-shielding portion 242a includes a first portion 242a1, a second portion 242a2, and a third portion 242a3. The first portion 242a1 overlaps the contact portion 226a of the light-emitting element 120B in plan view. Thus, light emission in the vicinity of the contact portion 226a of the light-emitting element 120B can be blocked by the first portion 242a1 of the first light-shielding portion 242a. The second portion 242a2 overlaps the contact portion 226a of the light-emitting element 120G2 in plan view. Thus, light emission in the vicinity of the contact portion 226a of the light-emitting element 120G2 can be blocked by the second portion 242a2 of the first light-shielding portion 242a. The third portion 242a3 is provided between the first portion 242a1 and the second portion 242a2 in plan view, and is coupled to each of the first portion 242a1 and the second portion 242a2. Thus, the coloring layer 241G in the same pixel can be divided into two portions aligned in the Y2 direction by the third portion 242a3 of the first light-shielding portion 242a in plan view.

The second light-shielding portion 242b includes a fourth portion 242b1, a fifth portion 242b2, and a sixth portion 242b3. The fourth portion 242b1 overlaps the contact portion 226a of the light-emitting element 120R in plan view. Thus, light emission in the vicinity of the contact portion 226a of the light-emitting element 120R can be blocked by the fourth portion 242b1 of the second light-shielding portion 242b. The fifth portion 242b2 overlaps the contact portion 226a of the light-emitting element 120G1 in plan view. Thus, light emission in the vicinity of the contact portion 226a of the light-emitting element 120G1 can be blocked by the fifth portion 242b2 of the second light-shielding portion 242b. The sixth portion 242b3 is provided between the fourth portion 242b1 and the fifth portion 242b2 in plan view, and is coupled to each of the fourth portion 242b1 and the fifth portion 242b2. Thus, the coloring layer 241G in different pixels can be divided into two portions aligned in the Y2 direction by the sixth portion 242b3 of the second light-shielding portion 242b in plan view.

As described above, such a light-shielding portion 242 may be constituted by a stack of the coloring layer 241R, the coloring layer 241B, and the coloring layer 241G. In this case, a black light-shielding portion 242 can be formed without using a material separate from the material constituting the coloring layer 241R, the coloring layer 241B, and the coloring layer 241G. Furthermore, in this case, the light-shielding portion 242 can be formed without performing a step separate from the formation of these coloring layers.

Furthermore, as described above, the electro-optical device 100 further includes the sealing layer 230 and the adhesion layer 243. The sealing layer 230 is disposed between the light-emitting element 120R, the light-emitting element 120B, the light-emitting element 120G1, and the light-emitting element 120G2 and the light-shielding portion 242. The adhesion layer 243 is disposed in contact with the light-shielding portion 242 between the sealing layer 230 and the light-shielding portion 242, and includes resin. Thus, the bonding strength between the light-shielding portion 242 and the sealing layer 230 can be enhanced.

### 1B. Second Embodiment

The second embodiment will be described. Note that in each of the following illustrations, for any component having a function similar to that in the first embodiment, the reference numeral used in the description of the first embodiment will be used, and detailed description thereof will be omitted as appropriate.

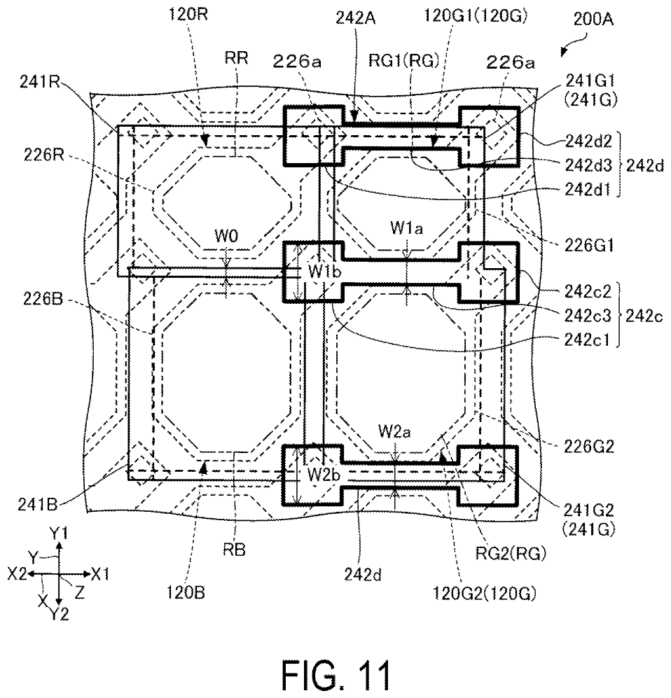

FIG. 11 is a plan view illustrating a portion of an element substrate 200A in the second embodiment. The element substrate 200A is similar to the element substrate 200 of the first embodiment described above except that the element substrate 200A includes a light-shielding portion 242A instead of the light-shielding portion 242. The light-shielding portion 242A is similar to the light-shielding portion 242 except that it has a different planar shape. Note that in FIG. 11, of the components constituting the element substrate 200A, components in one pixel P are representatively illustrated. Furthermore, in FIG. 11, illustration of the overcoat layer 250 to be described later is omitted for ease of view.

As illustrated in FIG. 11, the light-shielding portion 242A includes a plurality of first light-shielding portions 242c and a plurality of second light-shielding portions 242d.

The first light-shielding portion 242c includes a first portion 242c1, a second portion 242c2, and a third portion 242c3. The first portion 242c1 overlaps the contact portion 226a of the light-emitting element 120B in plan view. The second portion 242c2 overlaps the contact portion 226a of the light-emitting element 120G2 in plan view. The third portion 242c3 is provided between the first portion 242c1 and the second portion 242c2 in plan view, and is coupled to each of the first portion 242c1 and the second portion 242c2.

Here, the third portion 242c3 overlaps the region between the light-emitting region RG1 and the light-emitting region RG2, and overlaps no contact portion 226a in plan view. Similar to the width W1 of the first embodiment described above, the width W1a of the third portion 242c3 in the direction along the Y-axis is larger than the overlapping width W0 between the coloring layer 241R and the coloring layer 241B, and is smaller than the distance L1 between the light-emitting region RG1 and the light-emitting region RG2.

In contrast, each of the first portion 242c1 and the second portion 242c2 does not overlap the region between the light-emitting region RG1 and the light-emitting region RG2, and overlaps the contact portion 226a in plan view. The width W1b of each of the first portion 242c1 and the second portion 242c2 in the direction along the Y-axis is larger than the width W1a of the third portion 242c3 in the direction along the Y-axis. It is only required that the width W1b does not overlap any of the light-emitting regions in plan view, and is determined as appropriate in accordance with the shape or size of each of the light-emitting regions.

Similarly, the second light-shielding portion 242d includes a fourth portion 242d1, a fifth portion 242d2, and a sixth portion 242d3. The fourth portion 242d1 overlaps the contact portion 226a of the light-emitting element 120R in plan view. The fifth portion 242d2 overlaps the contact portion 226a of the light-emitting element 120G1 in plan view. The sixth portion 242d3 is provided between the fourth portion 242d1 and the fifth portion 242d2 in plan view, and is coupled to each of the fourth portion 242d1 and the fifth portion 242d2. Here, the width W2b of each of the fourth portion 242d1 and the fifth portion 242d2 in the direction along the Y-axis is larger than the width W2a of the sixth portion 242d3 in the direction along the Y-axis.

In the example illustrated in FIG. 11, the planar shape of each of the first portion 242c1, the second portion 242c2, the fourth portion 242d1, and the fifth portion 242d2 is a quadrangle including four sides along the X-axis and Y-axis. Furthermore, in the example illustrated in FIG. 11, the planar shapes and sizes of the first light-shielding portion 242c and the second light-shielding portion 242d are the same as each other. Note that the planar shapes and sizes of the first light-shielding portion 242c and the second light-shielding portion 242d may be different from each other.

In the second embodiment described above as well, similar to the first embodiment described above, the difference between the light distribution characteristics of the light emitted from the light-emitting region RG1 and the light-emitting region RG2 and the light distribution characteristics of the light emitted from the light-emitting region RR and the light-emitting region RB can be reduced. In the present embodiment, as described above, the width W1b of each of the first portion 242c1 and the second portion 242c2 in the direction along the Y-axis is larger than the width W1a of the third portion 242c3 in the direction along the Y-axis. Thus, light emission in the vicinity of the respective contact portions 226a of the light-emitting element 120B and the light-emitting element 120G2 can be blocked by the first portion 242c1 and the second portion 242c2 of the first light-shielding portion 242c, while the light from the light-emitting region RB and the light-emitting region RG2 are prevented from being blocked more than necessary by the third portion 242c3 of the first light-shielding portion 242c. Furthermore, the width W2b of each of the fourth portion 242d1 and the fifth portion 242d2 in the direction along the Y-axis is larger than the width W2a of the sixth portion 242d3 in the direction along the Y-axis. Thus, light emission in the vicinity of the respective contact portions 226a of the light-emitting element 120R and the light-emitting element 120G1 can be blocked by the fourth portion 242d1 and the fifth portion 242d2 of the second light-shielding portion 242d, while the light from the light-emitting region RR and the light-emitting region RG1 are prevented from being blocked more than necessary by the sixth portion 242d3 of the second light-shielding portion 242d.

### 1C. Third Embodiment

The third embodiment will be described. Note that in each of the following illustrations, for any component having a function similar to that in the first embodiment, the reference numeral used in the description of the first embodiment will be used, and detailed description thereof will be omitted as appropriate.

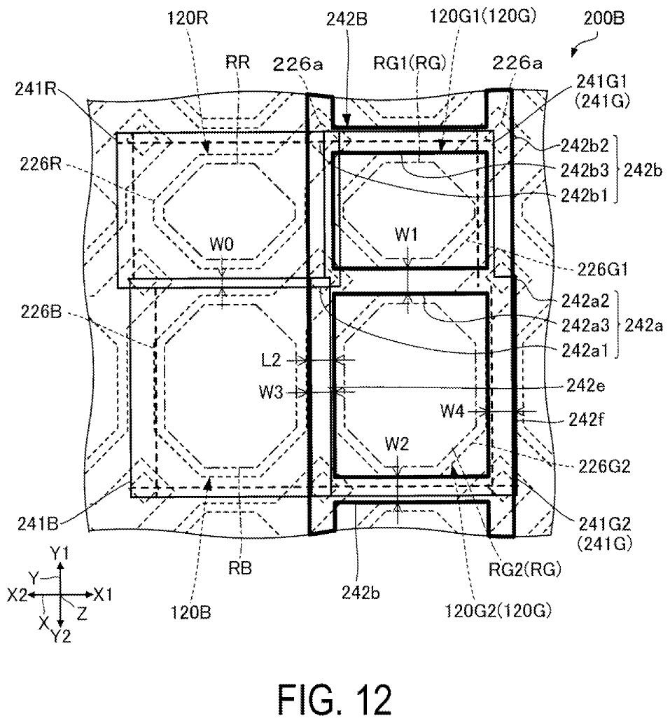

FIG. 12 is a plan view illustrating a portion of an element substrate 200B in the third embodiment. The element substrate 200B is similar to the element substrate 200 of the first embodiment described above except that the element substrate 200B includes a light-shielding portion 242B instead of the light-shielding portion 242. The light-shielding portion 242B is similar to the light-shielding portion 242 except that it has a different planar shape. Note that in FIG. 12, of the components constituting the element substrate 200B, components in one pixel P are representatively illustrated. Furthermore, in FIG. 12, illustration of the overcoat layer 250 to be described later is omitted for ease of view.

As illustrated in FIG. 12, the light-shielding portion 242B includes a plurality of first light-shielding portions 242a, a plurality of second light-shielding portions 242b, a plurality of third light-shielding portions 242e, and a plurality of fourth light-shielding portions 242f, and forms a ladder shape in plan view.

The third light-shielding portion 242e is disposed at a position overlapping the region between the light-emitting regions RR and RB and the light-emitting regions RG1 and RG2 in the same pixel P in plan view, extends in the direction along the Y-axis, and is coupled to each of the first light-shielding portion 242a and the second light-shielding portion 242b. Furthermore, the third light-shielding portion 242e overlaps the overlapping portion between the coloring layers 241R and 241B and the coloring layer 241G in the same pixel P in plan view.

In the present embodiment, the width W3 of the third light-shielding portion 242e in the direction along the X-axis is constant over the entire length in the direction along the Y-axis. Here, the width W3 is smaller than the distance L2 between the light-emitting region RR and the light-emitting region RG1, or between the light-emitting region RB and the light-emitting region RG2.

On the other hand, the fourth light-shielding portion 242f is configured in a manner similar to that of the third light-shielding portion 242e except that it is differently disposed. Here, the fourth light-shielding portion 242f is disposed at a position overlapping the region between the light-emitting regions RR and RB and the light-emitting regions RG1 and RG2 in different pixels P in plan view, extends in the direction along the Y-axis, and is coupled to each of the first light-shielding portion 242a and the second light-shielding portion 242b. Furthermore, the fourth light-shielding portion 242f overlaps the overlapping portion between the coloring layers 241R and 241B and the coloring layer 241G in different pixels P in plan view.

In the third embodiment described above as well, similar to the first embodiment described above, the difference between the light distribution characteristics of the light emitted from the light-emitting region RG1 and the light-emitting region RG2 and the light distribution characteristics of the light emitted from the light-emitting region RR and the light-emitting region RB can be reduced. In the present embodiment, as described above, the light-shielding portion 242B includes the third light-shielding portion 242e and the fourth light-shielding portion 242f. The third light-shielding portion 242e is provided between the first portion 242a1 and the fourth portion 242b1 in plan view, and is coupled to each of the first portion 242a1 and the fourth portion 242b1. The fourth light-shielding portion 242f is provided between the second portion 242a2 and the fifth portion 242b2 in plan view, and is coupled to each of the second portion 242a2 and the fifth portion 242b2. Using such a light-shielding portion 242B having a ladder shape makes it possible, even when unintended light emission occurs across the entire outer peripheral edge of each of the light-emitting regions, to block the light emission by the light-shielding portion 242B.

### 1D. Fourth Embodiment

The fourth embodiment will be described. Note that in each of the following illustrations, for any component having a function similar to that in the first embodiment, the reference numeral used in the description of the first embodiment will be used, and detailed description thereof will be omitted as appropriate.

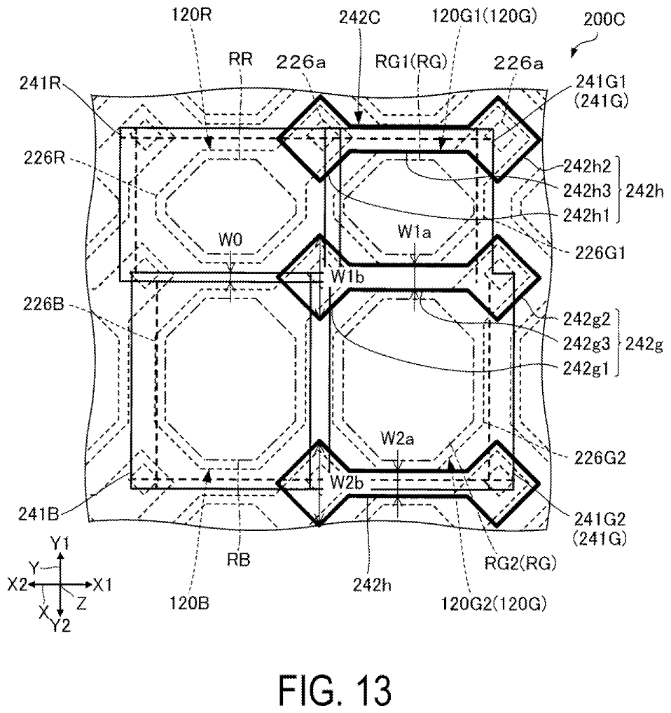

FIG. 13 is a plan view illustrating a portion of an element substrate 200C in the fourth embodiment. The element substrate 200C is similar to the element substrate 200 of the first embodiment described above except that the element substrate 200C includes a light-shielding portion 242C instead of the light-shielding portion 242. The light-shielding portion 242C is similar to the light-shielding portion 242 except that it has a different planar shape. Note that in FIG. 13, of the components constituting the element substrate 200C, components in one pixel P are representatively illustrated. Furthermore, in FIG. 13, illustration of the overcoat layer 250 to be described later is omitted for ease of view.

As illustrated in FIG. 13, the light-shielding portion 242C includes a plurality of first light-shielding portions 242g and a plurality of second light-shielding portions 242h.

The first light-shielding portion 242g includes a first portion 242g1, a second portion 242g2, and a third portion 242g3. Here, the third portion 242g3 is similar to the third portion 242c3 of the second embodiment described above. The first portion 242g1 and the second portion 242g2 are similar to the first portion 242c1 and the second portion 242c2 of the second embodiment described above except that they have different planar shapes.

Similarly, the second light-shielding portion 242h includes a fourth portion 242h1, a fifth portion 242h2, and a sixth portion 242h3. Here, the sixth portion 242h3 is similar to the sixth portion 242d3 of the second embodiment described above. The fourth portion 242h1 and the fifth portion 242h2 are similar to the fourth portion 242d1 and the fifth portion 242d2 of the second embodiment described above except that they have different planar shapes.

In the example illustrated in FIG. 13, the planar shape of each of the first portion 242g1, the second portion 242g2, the fourth portion 242h1, and the fifth portion 242h2 is a shape including four sides inclined relative to the X-axis and the Y-axis. Furthermore, in the example illustrated in FIG. 13, the planar shapes and sizes of the first light-shielding portion 242g and the second light-shielding portion 242h are the same as each other. Note that the planar shapes and sizes of the first light-shielding portion 242g and the second light-shielding portion 242h may be different from each other. For example, the planar shape of each of the first portion 242g1, the second portion 242g2, the fourth portion 242h1, and the fifth portion 242h2 may be a shape having a rounded portion.

In the fourth embodiment described above as well, similar to the first embodiment described above, the difference between the light distribution characteristics of the light emitted from the light-emitting region RG1 and the light-emitting region RG2 and the light distribution characteristics of the light emitted from the light-emitting region RR and the light-emitting region RB can be reduced. In the present embodiment, as described above, the shape of each of the first portion 242g1 and the second portion 242g2 is a shape that conforms to the shape between light-emitting regions. Thus, light emission in the vicinity of the respective contact portions 226a of the light-emitting element 120B and the light-emitting element 120G2 can be efficiently blocked. Similarly, the shape of each of the fourth portion 242h1 and the fifth portion 242h2 is a shape that conforms to the shape between light-emitting regions. Thus, light emission in the vicinity of the respective contact portions 226a of the light-emitting element 120R and the light-emitting element 120G1 can be efficiently blocked.

### 1E. Fifth Embodiment

The fifth embodiment will be described. Note that in each of the following illustrations, for any component having a function similar to that in the first embodiment, the reference numeral used in the description of the first embodiment will be used, and detailed description thereof will be omitted as appropriate.

FIG. 14 is a plan view illustrating a portion of an element substrate 200D in the fifth embodiment. The element substrate 200D is similar to the element substrate 200 of the first embodiment described above except that the element substrate 200D includes a light-shielding portion 242D instead of the light-shielding portion 242. The light-shielding portion 242D is similar to the light-shielding portion 242 except that it has a different planar shape. Note that in FIG. 14, of the components constituting the element substrate 200D, components in one pixel P are representatively illustrated. Furthermore, in FIG. 14, illustration of the overcoat layer 250 to be described later is omitted for ease of view.

As illustrated in FIG. 14, the light-shielding portion 242D includes a plurality of first light-shielding portions 242g, a plurality of second light-shielding portions 242h, a plurality of third light-shielding portions 242e, and a plurality of fourth light-shielding portions 242f, and forms a ladder shape in plan view. Here, the width W5 of each of the first portion 242g1 and the fourth portion 242h1 in the direction along the X-axis is larger than the width W3 of the third light-shielding portion 242e in the direction along the X-axis. Similarly, the width W6 of each of the second portion 242g2 and the fifth portion 242h2 in the direction along the X-axis is greater than the width of the fourth light-shielding portion 242f in the direction along the X-axis.

In the fifth embodiment described above as well, similar to the first embodiment described above, the difference between the light distribution characteristics of the light emitted from the light-emitting region RG1 and the light-emitting region RG2 and the light distribution characteristics of the light emitted from the light-emitting region RR and the light-emitting region RB can be reduced. In the present embodiment, as described above, the width W5 is larger than the width W3, and the width W6 is larger than the width W4. Thus, light emission in the vicinity of the contact portion 226a can be blocked by the first light-shielding portion 242g and the second light-shielding portion 242h, while the light from each of the light-emitting regions is prevented from being blocked more than necessary by the third light-shielding portion 242e and the fourth light-shielding portion 242f.

### 1F. Modified Examples

Each of the embodiments illustrated above can be variously modified. Specific modified aspects applicable to each of the embodiments described above will be illustrated below. Two or more aspects arbitrarily selected from the illustrations below can be combined as appropriate as long as mutual contradiction does not arise. Furthermore, each modified aspect of the first embodiment illustrated below is applicable to the second embodiment as appropriate as long as mutual contradiction does not arise.

### 1F-1. Modified Example 1

FIG. 15 is a cross-sectional view illustrating the coloring layers 241R, 241G, and 241B, the light-shielding portion 242, and the overcoat layer 250 of a modified example 1. The modified example 1 is similar to the first embodiment described above except that the thicknesses of the coloring layers 241R and 241B are different. In the modified example 1, the thickness of each of the coloring layers 241R and 241B is thicker than the thickness of the light-shielding portion 242, and the thickness of the coloring layer 241R is thicker than the thickness of the coloring layer 241B. In the modified example 1 described above as well, similar to the first embodiment described above, the difference between the light distribution characteristics of the light emitted from the light-emitting region RG1 and the light-emitting region RG2 and the light distribution characteristics of the light emitted from the light-emitting region RR and the light-emitting region RB can be reduced.

### 1F-2. Modified Example 2

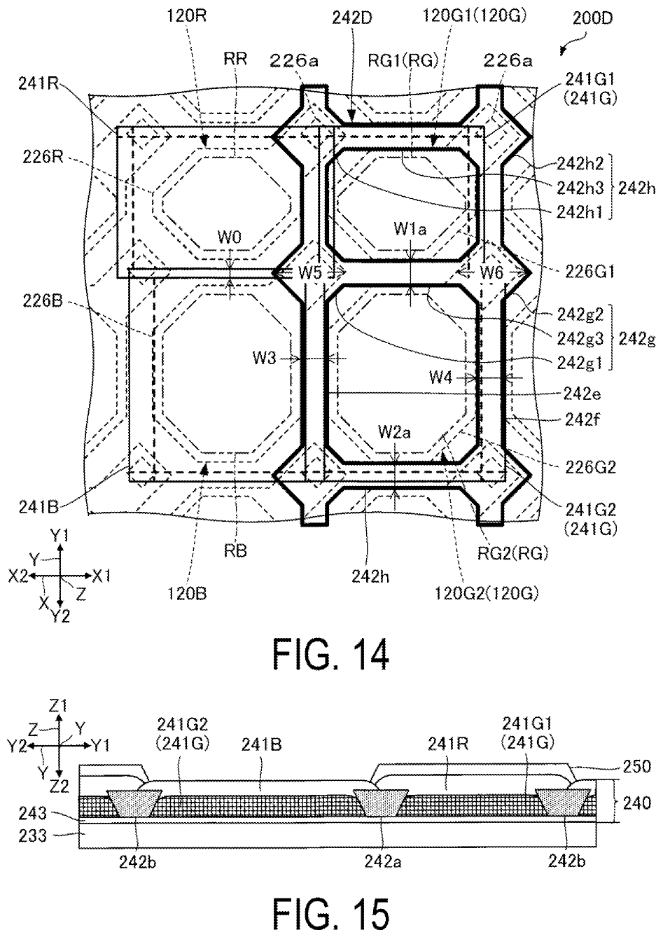

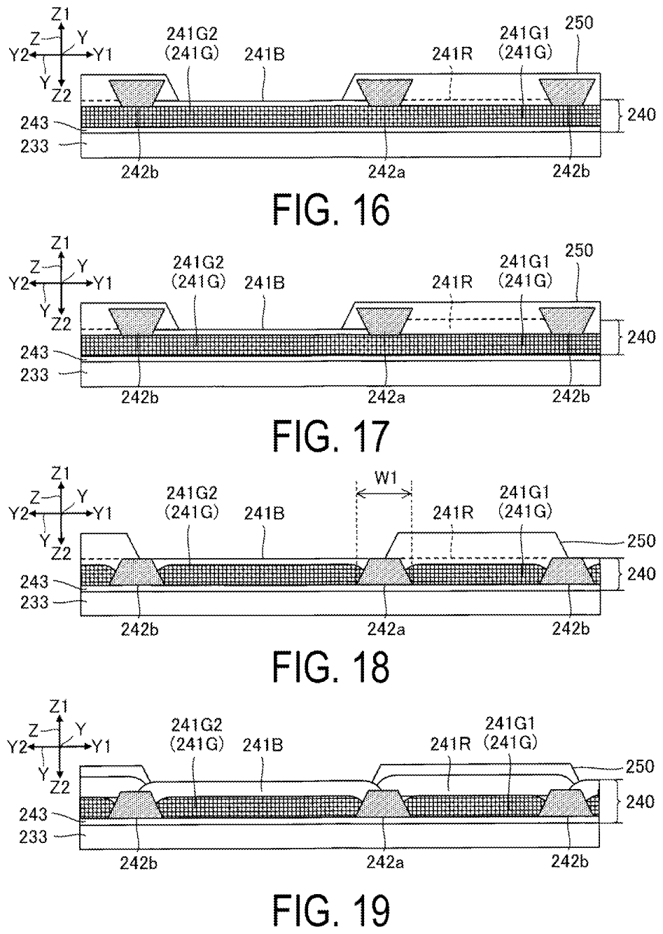

FIG. 16 is a cross-sectional view illustrating the coloring layers 241R, 241G, and 241B, the light-shielding portion 242, and the overcoat layer 250 of a modified example 2. The modified example 2 is similar to the first embodiment described above except that the light-shielding portion 242 is differently disposed. In the modified example 2, the light-shielding portion 242 is disposed on the coloring layer 241G. Here, the overcoat layer 250 is disposed so as to fill the step formed by the light-shielding portion 242. In the modified example 2 described above as well, similar to the first embodiment described above, the difference between the light distribution characteristics of the light emitted from the light-emitting region RG1 and the light-emitting region RG2 and the light distribution characteristics of the light emitted from the light-emitting region RR and the light-emitting region RB can be reduced.

### 1F-3. Modified Example 3

FIG. 17 is a cross-sectional view illustrating the coloring layers 241R, 241G, and 241B, the light-shielding portion 242, and the overcoat layer 250 of a modified example 3. The modified example 3 is similar to the modified example 2 described above except that the thicknesses of the coloring layers 241R, 241G, and 241B are different. In the modified example 3, similar to the modified example 1, the thickness of each of the coloring layers 241R and 241B is thicker than the thickness of the light-shielding portion 242, and the thickness of the coloring layer 241R is thicker than the thickness of the coloring layer 241B. In the modified example 3 described above as well, similar to the first embodiment described above, the difference between the light distribution characteristics of the light emitted from the light-emitting region RG1 and the light-emitting region RG2 and the light distribution characteristics of the light emitted from the light-emitting region RR and the light-emitting region RB can be reduced.

### 1F-4. Modified Example 4

FIG. 18 is a cross-sectional view illustrating the coloring layers 241R, 241G, and 241B, the light-shielding portion 242, and the overcoat layer 250 of a modified example 4. The modified example 4 is similar to the first embodiment described above except that the cross-sectional shape of the light-shielding portion 242 is different. In the modified example 4, when viewed in a cross section orthogonal to the Y-axis, each of the first light-shielding portion 242a and the second light-shielding portion 242b forms a trapezoid of which the width increases toward the Z2 direction. Such a light-shielding portion 242 has an advantage in that bubbles are less likely to remain between the coloring layer 241G and the light-shielding portion 242 when forming the coloring layer 241G after the light-shielding portion 242 is formed. The light-shielding portion 242 having such a cross-sectional shape is formed, for example, by using a positive photosensitive resin material as constituent material. In the modified example 4 described above as well, similar to the first embodiment described above, the difference between the light distribution characteristics of the light emitted from the light-emitting region RG1 and the light-emitting region RG2 and the light distribution characteristics of the light emitted from the light-emitting region RR and the light-emitting region RB can be reduced.

### 1F-5. Modified Example 5

FIG. 19 is a cross-sectional view illustrating the coloring layers 241R, 241G, and 241B, the light-shielding portion 242, and the overcoat layer 250 of a modified example 5. The modified example 5 is similar to the modified example 4 described above except that the thicknesses of the coloring layers 241R and 241B are different. In the modified example 5, the thickness of each of the coloring layers 241R and 241B is thicker than the thickness of the light-shielding portion 242, and the thickness of the coloring layer 241R is thicker than the thickness of the coloring layer 241B. In the modified example 5 described above as well, similar to the first embodiment described above, the difference between the light distribution characteristics of the light emitted from the light-emitting region RG1 and the light-emitting region RG2 and the light distribution characteristics of the light emitted from the light-emitting region RR and the light-emitting region RB can be reduced.

### 1F-6. Modified Example 6

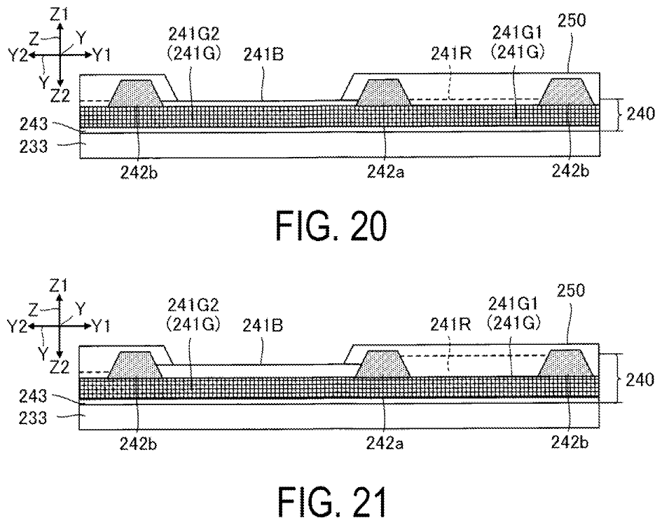

FIG. 20 is a cross-sectional view illustrating the coloring layers 241R, 241G, and 241B, the light-shielding portion 242, and the overcoat layer 250 of a modified example 6. The modified example 6 is similar to the modified example 4 described above except that the light-shielding portion 242 is differently disposed. In the modified example 6, the light-shielding portion 242 is disposed on the coloring layer 241G. Here, the overcoat layer 250 is disposed so as to fill the step formed by the light-shielding portion 242. In the modified example 6 described above as well, similar to the first embodiment described above, the difference between the light distribution characteristics of the light emitted from the light-emitting region RG1 and the light-emitting region RG2 and the light distribution characteristics of the light emitted from the light-emitting region RR and the light-emitting region RB can be reduced.

### 1F-7. Modified Example 7

FIG. 21 is a cross-sectional view illustrating the coloring layers 241R, 241G, and 241B, the light-shielding portion 242, and the overcoat layer 250 of a modified example 7. The modified example 7 is similar to the modified example 6 described above except that the thicknesses of the coloring layers 241R, 241G, and 241B are different. In the modified example 7, similar to the modified example 1, the thickness of each of the coloring layers 241R and 241B is thicker than the thickness of the light-shielding portion 242, and the thickness of the coloring layer 241R is thicker than the thickness of the coloring layer 241B. In the modified example 7 described above as well, similar to the first embodiment described above, the difference between the light distribution characteristics of the light emitted from the light-emitting region RG1 and the light-emitting region RG2 and the light distribution characteristics of the light emitted from the light-emitting region RR and the light-emitting region RB can be reduced.

### 1F-8. Modified Example 8

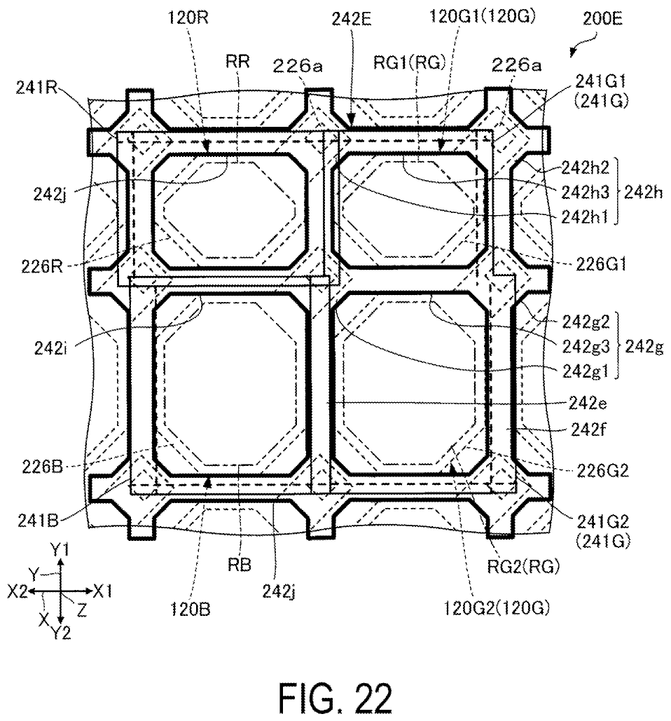

FIG. 22 is a plan view illustrating a portion of an element substrate 200E in a modified example 8. The element substrate 200E is similar to the element substrate 200 of the first embodiment described above except that the element substrate 200E includes a light-shielding portion 242E instead of the light-shielding portion 242. The light-shielding portion 242E is similar to the light-shielding portion 242 except that it has a different planar shape. Note that in FIG. 22, of the components constituting the element substrate 200E, components in one pixel P are representatively illustrated. Furthermore, in FIG. 22, illustration of the overcoat layer 250 to be described later is omitted for ease of view.

As illustrated in FIG. 22, the light-shielding portion 242E includes a plurality of first light-shielding portions 242g, a plurality of second light-shielding portions 242h, a plurality of third light-shielding portions 242e, a plurality of fourth light-shielding portions 242f, a plurality of fifth light-shielding portions 242i, and a plurality of sixth light-shielding portions 242j, and forms a lattice in plan view.

Here, the fifth light-shielding portion 242i is disposed at a position overlapping the region between the light-emitting region RR and the light-emitting region RB in the same pixel P in plan view, extends in the direction along the X-axis, and is coupled to each of the two first light-shielding portions 242g adjacent to each other in the direction along the X-axis. Furthermore, the fifth light-shielding portion 242i overlaps the overlapping portion between the coloring layer 241R and the coloring layer 241B in the same pixel P in plan view. Note that the fifth light-shielding portion 242i is configured in a manner similar to that of the third portion 242g3 of the first light-shielding portion 242g except that it is differently disposed.

On the other hand, the sixth light-shielding portion 242j is configured in a manner similar to that of the fifth light-shielding portion 242i except that it is differently disposed. Here, the sixth light-shielding portion 242j is disposed at a position overlapping the region between the light-emitting region RR and the light-emitting region RB in different pixels P in plan view, extends in the direction along the X-axis, and is coupled to each of the two second light-shielding portions 242h adjacent to each other in the direction along the X-axis. Furthermore, the sixth light-shielding portion 242j overlaps the overlapping portion between the coloring layer 241R and the coloring layer 241B in different pixels P in plan view. Note that the sixth light-shielding portion 242j is configured in a manner similar to that of the sixth portion 242h3 of the second light-shielding portion 242h except that it is differently disposed.

In the modified example 8 described above as well, similar to the first embodiment described above, the difference between the light distribution characteristics of the light emitted from the light-emitting region RG1 and the light-emitting region RG2 and the light distribution characteristics of the light emitted from the light-emitting region RR and the light-emitting region RB can be reduced.

### 1F-9. Modified Example 9

In the above-described embodiments, the light-emitting element 120 has an optical resonance structure with a different resonance wavelength for each color. However, the light-emitting element 120 need not have an optical resonance structure. The light-emitting element layer 220 may also include, for example, a partition dividing the organic layer 228 by the light-emitting elements 120. The light-emitting element 120 may also contain a different luminescent material for each sub-pixel P0. The pixel electrode 226 may also have light reflectivity. In that case, the reflection layer 222 may be omitted. Furthermore, although the common electrode 229 is common to a plurality of light-emitting elements 120, an individual cathode may be provided for each light-emitting element 120.

Furthermore, in the above-described embodiments, a configuration is illustrated in which the light distribution characteristics when the viewpoint is changed along the X-axis are improved. However, the present disclosure is not limited to this illustration. For example, when it is desired to improve the light distribution characteristics when the viewpoint is changed along the Y-axis, it is only required that the configuration described above is rotated by 90° about the Z-axis.

Furthermore, in the above-described embodiments, a configuration is illustrated in which the sub-pixel PG includes two light-emitting elements 120G1 and 120G2. However, the present disclosure is not limited to this configuration, and the light-emitting elements 120G1 and 120G2 may be integrated to form one light-emitting element. In this case, this light-emitting element is the “third light-emitting element”.

### 2. Electronic Apparatus

The electro-optical device 100 of the above-described embodiments is applicable to various electronic apparatuses.

### 2-1. Head-mounted Display

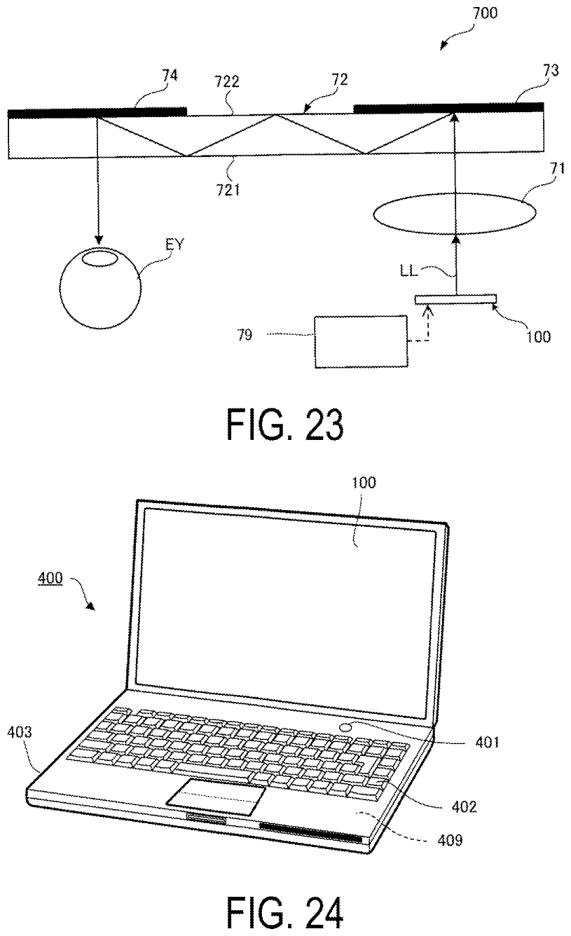

FIG. 23 is a view schematically illustrating a virtual image display device 700 that is an example of an electronic apparatus. The virtual image display device 700 illustrated in FIG. 23 is a head-mounted display (HMD) mounted on a head of an observer and configured to display an image. The virtual image display device 700 includes the electro-optical device 100 described above, a collimator 71, a light guide 72, a first reflection-type volume hologram 73, a second reflection-type volume hologram 74, and a control unit 79. Note that the light emitted from the electro-optical device 100 is emitted as image light LL. Furthermore, the configuration of each of the above-described embodiments or modified examples is applicable to the electro-optical device 100.

The control unit 79 includes, for example, a processor and a memory. The control unit 79 controls the operation of the electro-optical device 100. The collimator 71 is disposed between the electro-optical device 100 and the light guide 72. The collimator 71 collimates the light emitted from the electro-optical device 100. The collimator 71 is constituted by a collimator lens or the like. The light collimated by the collimator 71 is incident on the light guide 72.

The light guide 72 has a flat plate shape. The light guide 72 is disposed extending in a direction intersecting the direction of the light incident via the collimator 71. Light is reflected and guided inside the light guide 72. A light incident port on which light is incident and a light emission port from which light is emitted are provided on a surface 721 of the light guide 72 facing the collimator 71. The first reflection-type volume hologram 73 as a diffractive optical element and the second reflection-type volume hologram 74 as a diffractive optical element are disposed on a surface 722 of the light guide 72 opposite to the surface 721. The first reflection-type volume hologram 73 is provided closer to the light emission port side than the second reflection-type volume hologram 74. The first reflection-type volume hologram 73 and the second reflection-type volume hologram 74 have interference fringes corresponding to a predetermined wavelength range, and diffract and reflect light in the predetermined wavelength range.

In the virtual image display device 700 having such a configuration, the image light LL incident into the light guide 72 from the light incident port travels while being repeatedly reflected, and is guided from the light emission port to a pupil EY of the observer, whereby the observer can observe an image constituted by a virtual image formed by the image light LL.

The virtual image display device 700 described above includes the electro-optical device 100, and the control unit 79 configured to control the operation of the electro-optical device 100. Thus, it is possible to provide a virtual image display device 700 having light distribution characteristics superior to those of the conventional ones.

Note that the virtual image display device 700 may include a synthesizing element such as a dichroic prism configured to synthesize light emitted from the electro-optical device 100. In this case, the virtual image display device 700 can include, for example, an electro-optical device 100 configured to emit light in a blue wavelength range, an electro-optical device 100 configured to emit light in a green wavelength range, and an electro-optical device 100 configured to emit light in a red wavelength range.

### 2-2. Personal Computer

FIG. 24 is a perspective view illustrating a personal computer 400 that is an example of an electronic apparatus. The personal computer 400 illustrated in FIG. 24 includes the electro-optical device 100, a main body 403 provided with a power switch 401 and a keyboard 402, and a control unit 409. The control unit 409 includes, for example, a processor and a memory. The control unit 409 controls the operation of the electro-optical device 100. The personal computer 400 includes the above-described electro-optical device 100, and thus has excellent quality. Note that the configuration of each of the above-described embodiments or modified examples is applicable to the electro-optical device 100.

Note that examples of the “electronic apparatus” including the electro-optical device 100 include, apart from the virtual image display device 700 illustrated in FIG. 23 and the personal computer 400 illustrated in FIG. 24, apparatuses disposed close to eyes such as digital scopes, digital binoculars, digital still cameras, and video cameras. Furthermore, the “electronic apparatus” including the electro-optical device 100 is applied as mobile phones, smartphones, personal digital assistants (PDA), car navigation devices, and vehicle-mounted display units. Furthermore, the “electronic apparatus” including the electro-optical device 100 is applied as illumination for illuminating with light.

The present disclosure has been described above based on the illustrated embodiments. However, the present disclosure is not limited thereto. Furthermore, the configuration of each part of the present disclosure may be replaced with any configuration that exhibits a function similar to that in the above-described embodiments. In addition, any configuration may be added to the configuration of each part of the present disclosure. Furthermore, in the present disclosure, any configurations of the above-described embodiments may be combined with each other.

What is claimed is:

1. An electro-optical device comprising:
a first light-emitting element including a first light-emitting region that is configured to emit light in a first wavelength range;
a second light-emitting element including a second light-emitting region that is disposed at a position adjacent to the first light-emitting region in a first direction and that is configured to emit light in a second wavelength range;
a third light-emitting element including a third light-emitting region that is disposed at a position adjacent to the first light-emitting region and the second light-emitting region in a second direction intersecting the first direction and that is configured to emit light in a third wavelength range;
a first coloring layer that is provided overlapping the first light-emitting region in a plan view and that is configured to transmit the light in the first wavelength range;
a second coloring layer that is provided overlapping the second light-emitting region in the plan view and that is configured to transmit the light in the second wavelength range;
a third coloring layer that is provided overlapping the third light-emitting region in the plan view and that is configured to transmit the light in the third wavelength range; and
a light-shielding portion including a first light-shielding portion that is provided in an island shape so as to divide the third light-emitting region into two portions along the first direction in the plan view and that is configured to block at least the light in the third wavelength range.

2. An electro-optical device comprising:
a first light-emitting element including a first light-emitting region that is configured to emit light in a first wavelength range;
a second light-emitting element including a second light-emitting region that is disposed at a position adjacent to the first light-emitting region in a first direction and that is configured to emit light in a second wavelength range;
a third light-emitting element including a third light-emitting region that is disposed at a position adjacent to the first light-emitting region in a second direction intersecting the first direction and that is configured to emit light in a third wavelength range;
a fourth light-emitting element including a fourth light-emitting region that is disposed at a position adjacent to the second light-emitting region in the second direction and that is configured to emit light in a third wavelength range;
a first coloring layer that is provided overlapping the first light-emitting region in a plan view and that is configured to transmit the light in the first wavelength range;
a second coloring layer that is provided overlapping the second light-emitting region in the plan view and that is configured to transmit the light in the second wavelength range;
a third coloring layer that is provided overlapping the third light-emitting region and the fourth light-emitting region in the plan view and that is configured to transmit the light in the third wavelength range; and
a light-shielding portion including a first light-shielding portion that is provided in an island shape so as to overlap a region between the third light-emitting region and the fourth light-emitting region in the plan view and that is configured to block at least the light in the third wavelength range.

3. The electro-optical device according to claim 2, comprising:
a first relay electrode electrically coupled to a first pixel electrode included in the first light-emitting element;
a second relay electrode electrically coupled to a second pixel electrode included in the second light-emitting element;
a third relay electrode electrically coupled to a third pixel electrode included in the third light-emitting element;
a fourth relay electrode electrically coupled to a fourth pixel electrode included in the fourth light-emitting element; and
an insulating layer provided between the first pixel electrode and the first relay electrode, between the second pixel electrode and the second relay electrode, between the third pixel electrode and the third relay electrode, and between the fourth pixel electrode and the fourth relay electrode;
wherein the first pixel electrode includes a first contact portion electrically coupled to the first relay electrode via a first contact hole provided in the insulating layer,
the second pixel electrode includes a second contact portion electrically coupled to the second relay electrode via a second contact hole provided in the insulating layer,
the third pixel electrode includes a third contact portion electrically coupled to the third relay electrode via a third contact hole provided in the insulating layer,
the fourth pixel electrode includes a fourth contact portion electrically coupled to the fourth relay electrode via a fourth contact hole provided in the insulating layer, and
the first light-shielding portion overlaps one of the first contact portion or the second contact portion and one of the third contact portion or the fourth contact portion in the plan view.

4. The electro-optical device according to claim 3, wherein the light-shielding portion overlaps the first contact portion, the second contact portion, the third contact portion, and the fourth contact portion in the plan view.

5. The electro-optical device according to claim 4, wherein
the first light-shielding portion includes
a first portion overlapping the second contact portion in the plan view,
a second portion overlapping the fourth contact portion in the plan view, and
a third portion that is provided between the first portion and the second portion in the plan view and that is coupled to each of the first portion and the second portion,
the light-shielding portion further includes a second light-shielding portion overlapping the first contact portion and the third contact portion in the plan view, and
the second light-shielding portion includes a fourth portion overlapping the first contact portion in the plan view,
a fifth portion overlapping the third contact portion in the plan view, and
a sixth portion that is provided between the fourth portion and the fifth portion in the plan view and that is coupled to each of the fourth portion and the fifth portion.

6. The electro-optical device according to claim 5, wherein
a width of each of the first portion and the second portion in the first direction is larger than a width of the third portion in the first direction and
a width of each of the fourth portion and the fifth portion in the first direction is larger than a width of the sixth portion in the first direction.

7. The electro-optical device according to claim 5, wherein
the light-shielding portion further includes
a third light-shielding portion that is provided between the first portion and the fourth portion in plan view and that is coupled to each of the first portion and the fourth portion and
a fourth light-shielding portion that is provided between the second portion and the fifth portion in the plan view and that is coupled to each of the second portion and the fifth portion.

8. The electro-optical device according to claim 6, wherein
the light-shielding portion further includes
a third light-shielding portion that is provided between the first portion and the fourth portion in the plan view and that is coupled to each of the first portion and the fourth portion and
a fourth light-shielding portion that is provided between the second portion and the fifth portion in the plan view and that is coupled to each of the second portion and the fifth portion.

9. The electro-optical device according to claim 7, wherein
a width of each of the first portion and the fourth portion in the second direction is larger than a width of the third light-shielding portion in the second direction and
a width of each of the second portion and the fifth portion in the second direction is larger than a width of the fourth light-shielding portion in the second direction.

10. The electro-optical device according to claim 8, wherein
a width of each of the first portion and the fourth portion in the second direction is larger than a width of the third light-shielding portion in the second direction and
a width of each of the second portion and the fifth portion in the second direction is larger than a width of the fourth light-shielding portion in the second direction.

11. The electro-optical device according to claim 2, wherein the light-shielding portion is constituted by a stack of the first coloring layer, the second coloring layer, and the third coloring layer.

12. The electro-optical device according to claim 2, further comprising:
a sealing layer disposed between the first light-emitting element, the second light-emitting element, the third light-emitting element, and the fourth light-emitting element and the light-shielding portion; and
an adhesion layer that is disposed in contact with the light-shielding portion between the sealing layer and the light-shielding portion and that includes resin.

13. An electronic apparatus comprising:
the electro-optical device according to claim 1; and
a control unit configured to control an operation of the electro-optical device.
